(19) United States
(12) Patent Application Publication
(10) Pub. No.: US 2025/0107260 A1
(43) Pub. Date: Mar. 27, 2025

(54) PHOTOELECTRIC CONVERSION APPARATUS, PHOTOELECTRIC CONVERSION SYSTEM, MOVING BODY, AND EQUIPMENT

(71) Applicant: CANON KABUSHIKI KAISHA, Tokyo (JP)

(72) Inventors: HIROSHI SEKINE, Kanagawa (JP); KAZUHIRO MORIMOTO, Kanagawa (JP); KOSEI UEHIRA, Tokyo (JP)

(21) Appl. No.: 18/894,465

(22) Filed: Sep. 24, 2024

(30) Foreign Application Priority Data
Sep. 27, 2023 (JP) 2023-165204
Jun. 19, 2024 (JP) 2024-098500

(51) Int. Cl. H01L 27/146

(52) U.S. Cl. CPC H10F 39/807; H10F 39/199; H10F 39/811

(57) ABSTRACT

A photoelectric conversion apparatus includes a substrate including a first surface and a second surface being a light incidence surface; photoelectric conversion elements including avalanche photodiode provided on the substrate; and a separation portion which separates the photoelectric conversion elements. Each photoelectric conversion element includes a first semiconductor region of a first conductivity type which constitutes the avalanche photodiode and a second semiconductor region of a second conductivity type which constitutes the avalanche photodiode, the separation portion includes a conductor and an insulator which is provided between the photoelectric conversion element and the conductor, the photoelectric conversion apparatus further comprises a third semiconductor region of the second conductivity type which encloses the insulator, and a thickness of the insulator is greater than a sum of a thickness of the third semiconductor region and a thickness of the insulator.

### BACKGROUND OF THE INVENTION

### Field of the Invention

The present invention relates to a photoelectric conversion apparatus, a photoelectric conversion system, a moving body, and equipment.

### Description of the Related Art

Photoelectric conversion apparatuses capable of detecting faint light on a single photon-level by utilizing avalanche multiplication are known. U.S. Patent Application Publication No. 2017/0186798 discloses a photoelectric conversion apparatus that electrically connects, by a stack structure, both a sensor chip, on which a plurality of pixels are arrayed, and a circuit chip, on which a circuit for performing signal processing is formed. The use of an avalanche photodiode (APD) in which a charge causes avalanche multiplication in the pixels in the sensor chip of the photoelectric conversion apparatus is disclosed.

Providing a separation portion between pixels is known to enable optical crosstalk (light leakage) between pixels to be suppressed. In addition, inclusion of metal in the separation portion is known to enable optical crosstalk to be further suppressed. Japanese Patent Application Laid-open No. 2022-186423 discloses a configuration in which a separation portion includes metal coated with an insulator.

In addition, Japanese Patent Application Laid-open No. 2021-34559 reports a phenomenon (avalanche emission) in which a large amount of electrons, generated while an APD is driven, recombine with holes and emit light. The document indicates that while a defect occurs, in which emitted light leaks into an adjacent pixel and causes a false signal, the leakage of light to the adjacent pixel can be suppressed by providing the separation portion with a trench structure that includes an insulating member, air, and metal.

In configurations in which the separation portion includes metal, a potential equivalent to an anode potential is applied to the metal in order to prevent breakdown.

However, when the potential is applied to metal, i.e., a conductor, a potential difference is created between the separation portion and the APD to which a cathode potential is applied and an electric field intensity between the separation portion and the APD increases. When the intensity of the electric field between the separation portion and the APD increases, noise attributable to the electric field more readily occurs.

### SUMMARY OF THE INVENTION

An object of the present invention is to provide a technique which, in a configuration in which a separation portion includes a conductor, enables a suppression effect of crosstalk to be enhanced while suppressing noise attributable to an electric field between the separation portion and an APD.

According to some embodiments, a photoelectric conversion apparatus includes a substrate including a first surface and a second surface, the second surface opposing the first surface and being a light incidence surface; a plurality of photoelectric conversion elements which are provided on the substrate, and each of which includes an avalanche photodiode; and a separation portion which separates the plurality of photoelectric conversion elements. Each of the plurality of photoelectric conversion elements includes a first semiconductor region of a first conductivity type to which a first potential is applied and which constitutes the avalanche photodiode and a second semiconductor region of a second conductivity type which constitutes the avalanche photodiode, the separation portion includes a conductor to which a second potential that differs from the first potential is applied and an insulator which is provided between the photoelectric conversion element and the conductor, in a direction parallel to the first surface, a thickness of the insulator at a first depth that is a same depth as the first semiconductor region is greater than the thickness of the insulator at a third depth positioned between a second depth that is a same depth as the second semiconductor region and the second surface, the photoelectric conversion apparatus further comprises a third semiconductor region of the second conductivity type which encloses the insulator, and in the direction parallel to the first surface, a thickness of the insulator at the first depth is greater than a sum of a thickness of the third semiconductor region and a thickness of the insulator at the third depth.

According to some embodiments, a photoelectric conversion apparatus includes a substrate including a first surface and a second surface, the second surface opposing the first surface and being a light incidence surface; a first photoelectric conversion element and a second photoelectric conversion element which are provided on the substrate, each of which including an avalanche photodiode; a separation portion which is positioned between the first photoelectric conversion element and the second photoelectric conversion element and which at least separates a first surface side; and a first wiring layer which is arranged on the first surface side of the substrate. The separation portion includes a conductor, a first insulator, and a second insulator, the first insulator and the second insulator are arranged between the conductor and the first photoelectric conversion element, a refractive index of the second insulator is higher than a refractive index of the first insulator, and the second insulator extends to the first wiring layer.

According to some embodiments, a photoelectric conversion system includes the photoelectric conversion apparatus as described above; and a signal processing portion which generates an image by using a signal output by the photoelectric conversion apparatus.

According to some embodiments, a moving body including the photoelectric conversion apparatus as described above, further includes a control portion which controls movement of the moving body by using a signal output by the photoelectric conversion apparatus.

According to some embodiments, equipment including the photoelectric conversion apparatus as described above, further includes at least any of: an optical apparatus corresponding to the photoelectric conversion apparatus; a control apparatus that controls the photoelectric conversion apparatus; a processing apparatus that processes a signal output from the photoelectric conversion apparatus; a display apparatus that displays information obtained by the photoelectric conversion apparatus; a storage apparatus that stores information obtained by the photoelectric conversion apparatus; and a mechanical apparatus that operates on a basis of information obtained by the photoelectric conversion apparatus.

Further features of the present invention will become apparent from the following description of exemplary embodiments with reference to the attached drawings.

### BRIEF DESCRIPTION OF THE DRAWINGS

FIG. 1 is a schematic view of a photoelectric conversion apparatus according to an embodiment.

FIG. 2 is a schematic view of a pixel substrate of the photoelectric conversion apparatus according to the embodiment.

FIG. 3 is a schematic view of a circuit substrate of the photoelectric conversion apparatus according to the embodiment.

FIGS. 4A and 4B represent configuration examples of a pixel circuit of the photoelectric conversion apparatus according to the embodiment.

FIG. 5 is a schematic view showing drive of the pixel circuit of the photoelectric conversion apparatus according to the embodiment.

FIGS. 6A to 6C are plan views of a photoelectric conversion apparatus according to a first embodiment.

FIGS. 7A and 7B are sectional views of the photoelectric conversion apparatus according to the first embodiment.

FIG. 8 is a sectional view of a photoelectric conversion apparatus as a comparative example.

FIGS. 9A to 9C are plan views of a photoelectric conversion apparatus according to a second embodiment.

FIGS. 10A and 10B are sectional views of the photoelectric conversion apparatus according to the second embodiment.

FIGS. 11A to 11C are plan views of a photoelectric conversion apparatus according to a third embodiment.

FIGS. 12A and 12B are sectional views of the photoelectric conversion apparatus according to the third embodiment.

FIGS. 13A to 13C are plan views of a photoelectric conversion apparatus according to a fourth embodiment.

FIGS. 14A and 14B are sectional views of the photoelectric conversion apparatus according to the fourth embodiment.

FIG. 15 is a plan view of a photoelectric conversion apparatus according to a fifth embodiment.

FIGS. 16A and 16B are sectional views of the photoelectric conversion apparatus according to the fifth embodiment.

FIG. 17 is a plan view of a photoelectric conversion apparatus according to a comparative example of the fifth embodiment.

FIGS. 18A and 18B are sectional views of the photoelectric conversion apparatus according to the comparative example of the fifth embodiment.

FIGS. 19A to 19E are sectional views of structural variations of a separation portion according to the fifth embodiment.

FIGS. 20A to 20C are sectional views of structural variations of the separation portion according to the fifth embodiment.

FIGS. 21A to 21D are sectional views of structural variations of the separation portion according to the fifth embodiment.

FIGS. 22A to 22C are sectional views of structural variations of the separation portion according to the fifth embodiment.

FIGS. 23A to 23D are plan views of a photoelectric conversion apparatus according to a sixth embodiment.

FIGS. 24A and 24B are sectional views of the photoelectric conversion apparatus according to the sixth embodiment.

FIGS. 25A to 25D are plan views of a photoelectric conversion apparatus according to a seventh embodiment.

FIGS. 26A and 26B are sectional views of the photoelectric conversion apparatus according to the seventh embodiment.

FIG. 27 is a diagram illustrating a photoelectric conversion system according to an eighth embodiment.

FIGS. 28A and 28B are diagrams illustrating a photoelectric conversion system and a moving body according to a ninth embodiment.

FIG. 29 is a diagram illustrating a distance image sensor according to a tenth embodiment.

FIG. 30 is a diagram illustrating an endoscopic surgery system according to an eleventh embodiment.

FIGS. 31A and 31B are diagrams illustrating smart glasses according to a twelfth embodiment.

FIGS. 32A and 32B are diagrams illustrating an electronic device according to a thirteenth embodiment.

FIG. 33 is a diagram illustrating an X-ray CT apparatus according to a fourteenth embodiment.

FIG. 34 is a diagram illustrating equipment according to a fifteenth embodiment.

### DESCRIPTION OF THE EMBODIMENTS

The modes described below are for implementing technical concepts of the present invention and are not intended to limit the present invention. Note that sizes and positional relationships of members shown in each of the drawings may sometimes be exaggerated for the sake of better understanding. In the following description, same components may be denoted by same numerals and descriptions thereof may be omitted.

Hereinafter, embodiments of the present invention will be described in detail with reference to the drawings. In the following description, terms that indicate a specific direction or a position (for example, “up”, “down”, “right”, “left” and other terms that contain these terms) will be used as necessary. Such terms are used for facilitating understanding of the embodiments with reference to the drawings and the meanings of the terms are not intended to limit the technical scope of the present invention in any way whatsoever.

In the present specification, a plan view refers to a view from a perpendicular direction with respect to a light incidence surface of a semiconductor layer. In addition, a sectional view refers to a view from a direction parallel to the light incidence surface of the semiconductor layer. When the light incidence surface of the semiconductor layer is a rough surface from a microscopic perspective, a plan view is to be defined with respect to the light incidence surface of the semiconductor layer when viewed from a macroscopic perspective.

The semiconductor layer has a first surface and a second surface which is a surface on an opposite side to the first surface and to which light is incident. In the present specification, a depth direction is a direction from the first surface of the semiconductor layer on which an avalanche photodiode (APD) is arranged toward the second surface of the semiconductor layer. Hereinafter, the “first surface” may be referred to as a “front surface” and the “second surface” may be referred to as a “rear surface”. A “depth” of a given point or a given region in the semiconductor layer means a distance of the point or the region from the first surface (front surface). When there are a point (or a region) Z1 of which a distance (depth) from the first surface is d1 and a point (or a region) Z2 of which a distance (depth) from the first surface is d2 and d1>d2 is satisfied, expressions such as “Z1 is deeper than Z2” and “Z2 is shallower than Z1” may be used. In addition, when there is a point (or a region) Z3 of which a distance (depth) from the first surface is d3 and d1>d3>d2 is satisfied, expressions such as “Z3 is at a depth between Z1 and Z2” and “Z3 is between Z1 and Z2 in the depth direction” may be used.

In the following description, an anode of an avalanche photodiode (APD) is to have a fixed potential and a signal is extracted from a cathode side. Therefore, a first conductivity type semiconductor region having, as a majority carrier, charges with a same polarity as a signal charge is an N-type semiconductor region and a second conductivity type semiconductor region having, as a majority carrier, charges with a different polarity from the signal charge is a P-type semiconductor region. It should be noted that the present invention holds true even in cases where the cathode of an APD is to have a fixed potential and a signal is extracted from the anode side. In this case, the first conductivity type semiconductor region having, as a majority carrier, charges with a same polarity as a signal charge is a P-type semiconductor region and the second conductivity type semiconductor region having, as a majority carrier, charges with a different polarity from the signal charge is an N-type semiconductor region. While a case where one of the nodes of an APD is to have a fixed potential will be described below, alternatively, potentials of both nodes may fluctuate.

In the present specification, simply using the term “impurity concentration” means a net impurity concentration after subtracting an amount compensated by inverse conductivity-type impurities. In other words, an “impurity concentration” refers to a net doping concentration. A region in which a P-type additive impurity concentration is higher than an N-type additive impurity concentration is a P-type semiconductor region. Conversely, a region in which an N-type additive impurity concentration is higher than a P-type additive impurity concentration is an N-type semiconductor region.

In addition, a connection between elements of a circuit may be described in the following embodiments. In this case, unless otherwise noted, elements of interest will be considered being electrically connected even if another element is interposed between the elements of interest. For example, let us assume that an element A is connected to one of a plurality of nodes of a capacitative element C and an element B is connected to another node of the capacitative element C. Even in this case, the element A and the element B will be considered being electrically connected unless otherwise noted. Furthermore, when elements are connected to each other without any interposed elements, the elements may be described as being directly connected to each other. In the example described above, when another element is not provided between the element A and the capacitative element C, the element A and the capacitative element C can be described as being directly connected to each other.

Metal members such as wiring and pads described in the present specification may be constituted of an elemental metal made of a single element or may be a mixture (alloy). For example, a wiring described as a copper wiring may be constituted by elemental copper or may be constructed to mainly contain copper but also contain other components. In addition, for example, a pad to be connected to an external terminal may be constituted by elemental aluminum or may be constructed to mainly contain aluminum but also contain other components. The copper wiring and the aluminum pad described above are merely examples and may be changed to various metals.

In addition, the wiring and the pad described above are examples of metal members that are used in a photoelectric conversion apparatus and can also be applied to other metal members.

In the respective embodiments presented below, an imaging apparatus will be mainly described as an example of a photoelectric conversion apparatus. However, the respective embodiments are not limited to an imaging apparatus and are also applicable to other examples of photoelectric conversion apparatuses. Such examples include a ranging apparatus (an apparatus for distance measurement or the like using focus detection or TOF (Time Of Flight)) and a photometric apparatus (an apparatus for measuring an amount of incident light or the like).

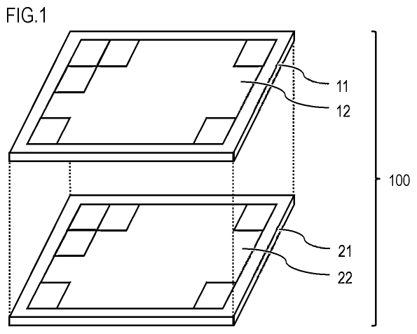

A common configuration shared by respective embodiments of a photoelectric conversion apparatus and a driving method thereof according to the present invention will be described with reference to FIGS. 1 to 5.

FIG. 1 is a diagram showing a configuration of a photoelectric conversion apparatus 100 according to an embodiment of the present invention. Hereinafter, a case where the photoelectric conversion apparatus 100 is a stacked photoelectric conversion apparatus will be described as an example. Specifically, a photoelectric conversion apparatus constructed by stacking two substrates, namely, a sensor substrate 11 and a circuit substrate 21 and electrically connecting the substrates will be described as an example. However, photoelectric conversion apparatuses are not limited thereto. For example, the photoelectric conversion apparatus may be a photoelectric conversion apparatus in which components of the sensor substrate 11 and components of the circuit substrate 21 described below are arranged on a common semiconductor layer. Hereinafter, a photoelectric conversion apparatus in which the components of the sensor substrate 11 and the components of the circuit substrate 21 are arranged on a common semiconductor layer will also be referred to as a non-stacked photoelectric conversion apparatus.

The sensor substrate 11 includes a first semiconductor layer that includes a photoelectric conversion element 102 to be described later and a first wiring structure. The circuit substrate 21 includes a second semiconductor layer that includes a circuit such as a signal processing portion 103 or the like to be described later and a second wiring structure. The photoelectric conversion apparatus 100 is constructed by stacking the second semiconductor layer, the second wiring structure, the first wiring structure, and the first semiconductor layer in this order.

FIG. 1 illustrates a back-side illuminated photoelectric conversion apparatus in which light is incident from a second surface (rear surface) and the circuit substrate 21 is arranged on a first surface (front surface) that is a surface on an opposite side to the second surface. In the case of a non-stacked photoelectric conversion apparatus, a surface on a side where a transistor of a signal processing circuit is arranged is referred to as a first surface. In the case of a front-side illuminated photoelectric conversion apparatus, the front surface is the second surface (light incidence surface) and the rear surface is the first surface.

While the sensor substrate 11 and the circuit substrate 21 will be described below as being diced chips, the substrates are not limited to chips. For example, each substrate may be a wafer. In addition, each substrate may be stacked in a wafer state and subsequently diced or each chip may be stacked and joined after being made into chips.

A pixel region 12 is arranged on the sensor substrate 11 and a circuit region 22 for processing a signal detected by the pixel region 12 is arranged on the circuit substrate 21.

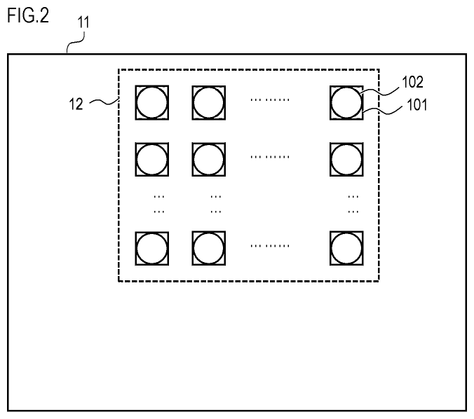

FIG. 2 is an arrangement diagram of the sensor substrate 11. Pixels 101 that include the photoelectric conversion element 102 including an avalanche photodiode (APD) are arrayed in a two-dimensional pattern to form the pixel region 12.

While the pixel 101 is typically a pixel for forming an image, when used for TOF (Time Of Flight), an image need not necessarily be formed. In other words, the pixel 101 may be a pixel for measuring a time of arrival of light and a light amount.

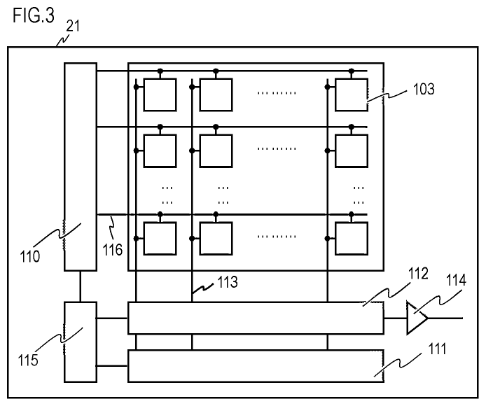

FIG. 3 is a configuration diagram of the circuit substrate 21. The circuit substrate 21 includes the signal processing portion 103 that processes a charge having been photoelectrically converted by the photoelectric conversion element 102 shown in FIG. 2, a readout circuit 112, a control pulse generating portion 115, a horizontal scan circuit portion 111, a signal line 113, a vertical scan circuit portion 110, a drive line 116, and an output circuit 114.

The photoelectric conversion element 102 shown in FIG. 2 and the signal processing portion 103 shown in FIG. 3 are electrically connected via a connecting wiring provided for each pixel.

The vertical scan circuit portion 110 receives a control pulse supplied from the control pulse generating portion 115 and supplies the control pulse to each pixel via the drive line 116. A logic circuit such as a shift register or an address decoder is used in the vertical scan circuit portion 110.

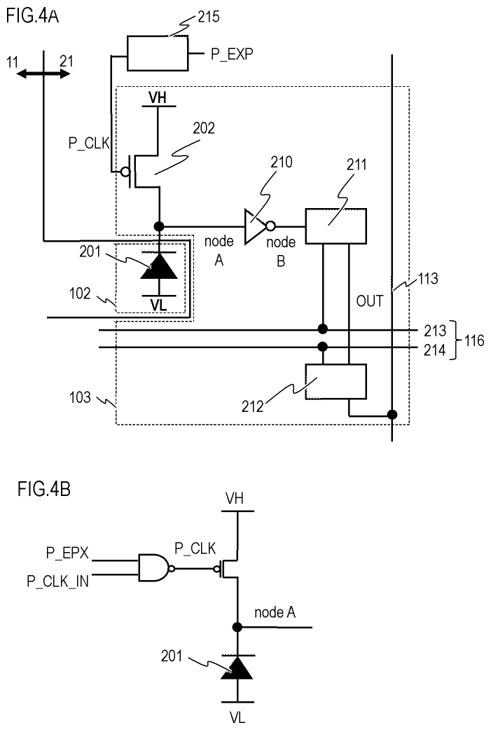

The control pulse generating portion 115 includes a signal generating portion 215 that generates a control signal P_CLK of a switch to be described later. As will be described later, the signal generating portion 215 generates a pulse signal that controls the switch. For example, the signal generating portion 215 may commonly generate the control signal P_CLK with respect to a plurality of pixels in the pixel region 12 as shown in FIG. 4A or generate the control signal P_CLK for each pixel as shown in FIG. 4B. When commonly generating the control signal P_CLK, the control signal P_CLK is commonly generated by associating, with an exposure period, at least any one of a period, the number of pulses, and a pulse width of a pulse signal P_EXP that controls an exposure period. In addition, when controlling the control signal P_CLK for each pixel, the signal can be generated using both an input signal P_CLK_IN that is output from the control pulse generating portion 115 and the signal P_EXP that controls the exposure period. For example, the control pulse generating portion 115 preferably includes a divider circuit. Accordingly, simple control can be realized and an increase in the number of elements can be suppressed.

A signal output from the photoelectric conversion element 102 of each pixel is processed by the signal processing portion 103. The signal processing portion 103 is provided with a counter, a memory, and the like and a digital value is stored in the memory.

The horizontal scan circuit portion 111 inputs a control pulse for sequentially selecting each row to the signal processing portion 103 in order to read a signal from the memory of each pixel that stores a digital signal.

For each selected row, a signal is output to the signal line 113 from the signal processing portion 103 of the pixel having been selected by the vertical scan circuit portion 110.

The signal output to the signal line 113 is output to an external recording portion or a signal processing portion of the photoelectric conversion apparatus 100 via the output circuit 114.

In FIG. 2, an array of the pixels 101 in the pixel region 12 may be arranged one-dimensionally. A function of the signal processing portion 103 need not necessarily be provided in each and every pixel 101 and, for example, a single signal processing portion 103 may be shared by a plurality of pixels 101 and signal processing may be performed sequentially.

FIGS. 4A and 4B are examples of a block diagram including equivalent circuits of FIGS. 2 and 3. FIG. 4A represents an example in which the signal generating portion 215 is commonly provided with respect to a plurality of pixels and FIG. 4B represents an example in which the control signal P_CLK can be controlled for each pixel. FIG. 4A will be described.

In FIG. 4A, the photoelectric conversion element 102 including an APD 201 is provided on the sensor substrate 11 and other members are provided on the circuit substrate 21.

The APD 201 generates a charge pair in accordance with incident light by photoelectric conversion. A voltage VL (first voltage) is supplied to an anode of the APD 201. In addition, a voltage VH (second voltage) that is higher than the voltage VL supplied to the anode is supplied to a cathode of the APD 201. The anode and the cathode are supplied with voltages with a reverse bias that causes the APD 201 to perform an avalanche multiplication operation. By creating a state where such voltages are supplied, a charge created by the incident light causes avalanche multiplication and an avalanche current is created.

When voltage of a reverse bias is supplied, the APD has a Geiger mode in which the APD operates at a potential difference between the anode and the cathode that is larger than a breakdown voltage and a linear mode in which the APD operates at a potential difference between the anode and the cathode that is in the vicinity of or smaller than the breakdown voltage. The APD operated in the Geiger mode is referred to as a SPAD. For example, the voltage VL (first voltage) is −30 V and the voltage VH (second voltage) is 1 V. The APD 201 may be operated either in the linear mode or in the Geiger mode. In the case of a SPAD, the potential difference increases as compared to an APD in the linear mode and a voltage-resistance effect becomes prominent.

A switch 202 is connected to a power line and the APD 201 to which the drive voltage VH is supplied. The switch 202 is connected to one node among the anode and the cathode of the APD 201. In addition, the switch 202 performs switching between a first potential difference at which the potential difference between the anode and the cathode of the APD 201 is avalanche-multiplied and a second potential difference at which the potential difference between the anode and the cathode of the APD 201 is not avalanche-multiplied. Hereinafter, switching from the second potential difference to the first potential difference will also be referred to as turning the switch 202 on and switching from the first potential difference to the second potential difference will also be referred to as turning the switch 202 off. The switch 202 functions as a quenching element. The switch 202 functions as a load circuit (quenching circuit) during signal multiplication due to the avalanche multiplication and acts to suppress the voltage to be supplied to the APD 201 to suppress avalanche multiplication (a quenching operation). In addition, by causing a current corresponding to the voltage drop due to the quenching operation to flow, the switch 202 acts to return the voltage supplied to the APD 201 to the drive voltage VH (a recharging operation). In other words, the switch 202 functions as a control circuit that controls an occurrence of avalanche multiplication in the APD 201.

The switch 202 can be constituted of, for example, a MOS (Metal Oxide Semiconductor) transistor. The control signal P_CLK of the switch 202 supplied from the signal generating portion 215 is applied to a gate electrode of the MOS transistor that constitutes the switch 202. In the present embodiment, on and off states of the switch 202 are controlled by controlling an applied voltage to the gate electrode of the switch 202.

The signal processing portion 103 includes a waveform shaping portion 210, a counter circuit 211, and a selection circuit 212. In the present specification, the signal processing portion 103 need only include at least any one of the waveform shaping portion 210, the counter circuit 211, and the selection circuit 212.

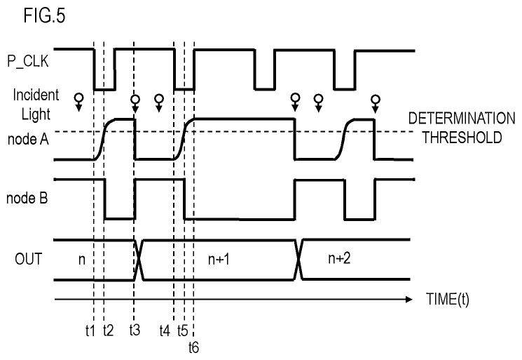

The waveform shaping portion 210 shapes a potential change of the cathode of the APD 201 that is obtained upon photon detection and outputs a pulse signal. A node on an input side of the waveform shaping portion 210 will be referred to as a node A and a node on an output side of the waveform shaping portion 210 will be referred to as a node B. The waveform shaping portion 210 varies an output potential from the node B depending on whether an input potential to the node A is equal to or higher than a predetermined value or lower than the predetermined value. For example, in FIG. 5, when the input potential to the node A becomes a high potential that is equal to or higher than a determination threshold, the output potential from the node B changes to a low level. In addition, when the input potential to the node A becomes a low potential that is lower than the determination threshold, the output potential from the node B changes to a high level. For example, an inverter circuit is used as the waveform shaping portion 210. While an example in which a single inverter is used as the waveform shaping portion 210 is shown in FIG. 4A, a circuit in which a plurality of inverters are connected in series may be used or another circuit with a waveform shaping effect may be used.

While a quenching operation and a recharging operation using the switch 202 can be performed in accordance with an avalanche multiplication in the APD 201, depending on a photon detection timing, a charge generated in the APD 201 may not be determined as an output signal. For example, let us assume a case where an avalanche multiplication has occurred in the APD 201, the node A has changed to a low level, and a recharging operation is being performed. Generally, the determination threshold of the waveform shaping portion 210 is set to a higher potential than a potential difference at which an avalanche multiplication occurs in the APD 201. When photons are incident to the APD 201 in a state where, due to a recharging operation, the potential of the node A is lower than the determination threshold and the potential can be avalanche-multiplied in the APD 201, an avalanche multiplication occurs in the APD 201 and a voltage of the node A drops. In other words, since the potential of the node A drops under a lower voltage than the determination threshold, a potential change that straddles the determination threshold does not occur and an output potential from the node B does not change. Therefore, a photon detection is no longer determined as a signal despite an occurrence of an avalanche multiplication. In particular, under a high luminance, since photons are consecutively incident to the APD 201 in a short period of time, incident light is less likely to be determined as a signal. Accordingly, the number of actually incident photons and an output signal more readily diverge from each other despite being under a high luminance.

In contrast, by applying the control signal P_CLK to the switch 202 to switch between the on-state and the off-state of the switch 202, a determination of a signal can be made even when photons are consecutively incident to the APD 201 in a short period of time. In FIG. 5, an example in which the control signal P_CLK is a pulse signal with a repetition period will be described. In other words, a mode in which the on-state and the off-state of the switch 202 are switched by a predetermined clock frequency will be described in FIG. 5. However, an effect of suppressing an increase in power consumption of the photoelectric conversion apparatus 100 can be produced even if the pulse signal is not a signal with a repetition period.

The counter circuit 211 counts pulse signals output from the waveform shaping portion 210 and stores a count value. In addition, when a control pulse pRES is supplied via a drive line 213, the signals stored in the counter circuit 211 are reset.

The selection circuit 212 is supplied with a control pulse pSEL via a drive line 214 shown in FIG. 4A from the vertical scan circuit portion 110 shown in FIG. 3 and switches between electric connection and non-connection of the counter circuit 211 and the signal line 113. For example, the selection circuit 212 includes a buffer circuit for outputting signals and the like.

A switch such as a transistor may be arranged between the switch 202 and the APD 201 and between the photoelectric conversion element 102 and the signal processing portion 103 to switch between electric connection and non-connection. In a similar manner, supply of the voltage VH or the voltage VL to be supplied to the photoelectric conversion element 102 may be electrically switched using a switch such as a transistor.

A configuration using the counter circuit 211 has been described in the present embodiment. However, the photoelectric conversion apparatus 100 which acquires a pulse detection timing using a Time to Digital Converter (hereinafter, TDC) and a memory in place of the counter circuit 211 may be adopted. In this case, a generation timing of a pulse signal output from the waveform shaping portion 210 is converted into a digital signal by the TDC. In order to measure a timing of a pulse signal, the TDC is supplied with a control pulse pREF (a referential signal) via a drive line from the vertical scan circuit portion 110 shown in FIG. 3. Using the control pulse pREF as a reference, the TDC acquires, as a digital signal, a value when an input timing of a signal output from each pixel is considered a relative time.

FIG. 5 is a diagram schematically showing a relationship among the control signal P_CLK of the switch, the potential of the node A, the potential of the node B, and the output signal. In the present embodiment, a state where the drive voltage VH is hardly supplied to the APD 201 is created when the control signal P_CLK is at a high level and a state where the drive voltage VH is supplied to the APD 201 is created when the control signal P_CLK is at a low level. The high level of the control signal P_CLK is, for example, 1 V, and the low level of the control signal P_CLK is, for example, 0 V. The switch is turned off when the control signal P_CLK is at the high level and the switch is turned on when the control signal P_CLK is at the low level. A resistance value of the switch when the control signal P_CLK is at the high level is higher than a resistance value of the switch when the control signal P_CLK is at the low level. When the control signal P_CLK is at the high level, since a recharging operation is less likely to be performed even if an avalanche multiplication occurs in the APD 201, the potential supplied to the APD 201 becomes equal to or lower than the breakdown voltage of the APD 201. Therefore, the avalanche multiplication operation in the APD 201 stops.

As shown in FIG. 4A, preferably, the switch 202 is constituted of one transistor and a quenching operation and a recharging operation are performed with one transistor. Accordingly, the number of circuits can be reduced as compared to a case where a quenching operation and a recharging operation are respectively performed by different circuit elements. In particular, when each pixel includes a counter circuit and an SPAD signal is read for each pixel, a circuit area used for a switch is preferably reduced in order to arrange the counter circuits and an effect produced by constituting the switch 202 with one transistor becomes prominent.

At time t1, the control signal P_CLK changes from the high level to the lower level, the switch is turned on, and a recharging operation of the APD 201 is started. Accordingly, a potential of the cathode of the APD 201 makes a transition to a high level. In addition, a state is created where the potential difference between potentials applied to the anode and the cathode of the APD 201 can be avalanche-multiplied. The potential of the cathode is the same as the node A. Therefore, when the potential of the cathode makes a transition from the low level to the high level, the potential of the node A equals or exceeds the determination threshold at time t2. At this point, the pulse signal output from the node B is inverted and changes from the high level to the low level. Subsequently, a state is created where a potential difference expressed as drive voltage VH-drive voltage VL is applied to the APD 201. The control signal P_CLK changes to the high level and the switch is turned off.

Next, when photons are incident to the APD 201 at time t3, an avalanche multiplication occurs in the APD 201 and the voltage of the cathode drops. In other words, the voltage of the node A drops. When the amount of voltage drop further increases and a voltage difference that is applied to the APD 201 decreases, the avalanche multiplication of the APD 201 stops in a similar manner to time t2 and a voltage level of the node A does not drop beyond a given constant value. When the voltage of the node A becomes lower than the determination threshold during the voltage drop of the node A, the voltage of the node B changes from the low level to the high level. In other words, a portion of the output waveform of the node A having exceeded the determination threshold is subjected to waveform shaping by the waveform shaping portion 210 and output as a signal from the node B. In addition, the signal is counted by a counter circuit and a count value of a counter signal that is output from the counter circuit increases by an amount corresponding to 1 LSB.

Photons are incident to the APD 201 between time t3 and time t4. However, since the switch is in the off-state and the applied voltage to the APD 201 does not create a potential difference that can be avalanche-multiplied, the voltage level of the node A does not exceed the determination threshold.

At time t4, the control signal P_CLK changes from the high level to the low level and the switch is turned on. Accordingly, a current that compensates for the amount of voltage drop from the drive voltage VH flows to the node A and the voltage of the node A makes a transition to the original voltage level. In this case, since the voltage of the node A equals or exceeds the determination threshold at time t5, the pulse signal of the node B is inverted and changes from the high level to the low level.

At time t6, the node A stabilizes at the original voltage level and the control signal P_CLK changes from the low level to the high level. Therefore, the switch is turned off. Hereinafter, potentials of each node, each signal line, and the like change in a similar manner according to the control signal P_CLK or incidence of photons as described above with respect to time t1 to time t6.

Hereinafter, photoelectric conversion apparatuses of the respective embodiments will be described.

### First Embodiment

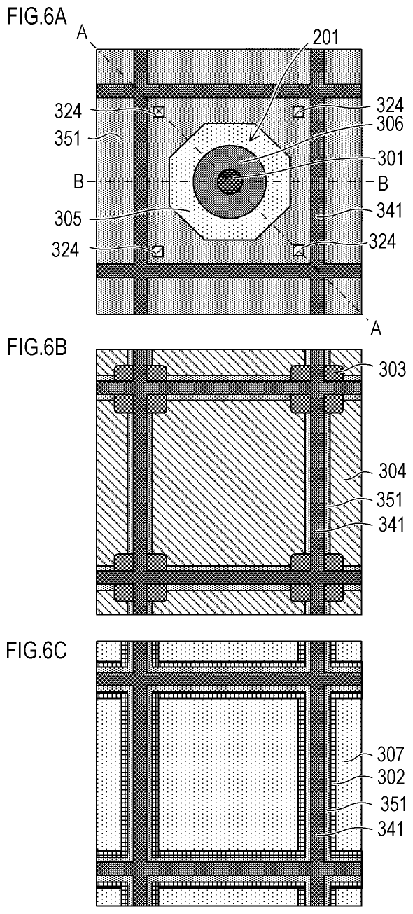

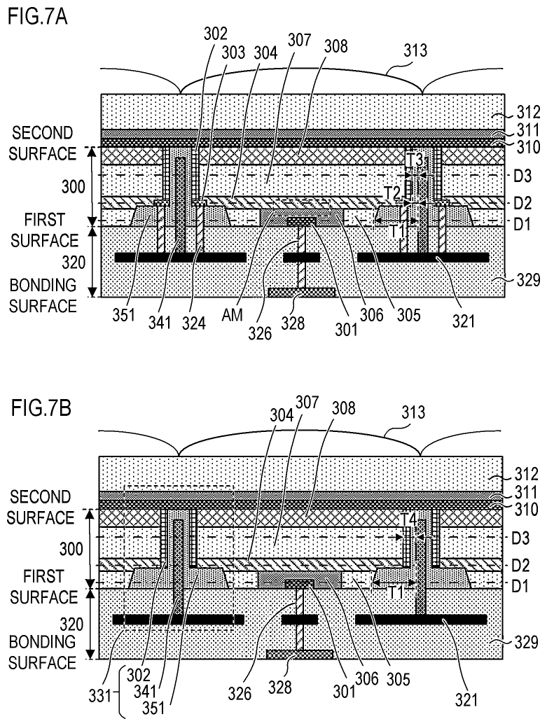

FIGS. 6A to 6C, 7A, and 7B show a structure of the sensor substrate 11 of a photoelectric conversion apparatus according to a first embodiment. FIG. 6A is a plan view at a depth D1 (first depth) that is a same depth as a first semiconductor region 301 shown in FIG. 7A. FIG. 6B is a plan view at a depth D2 (second depth) that is a same depth as a fourth semiconductor region 304 shown in FIG. 7A. FIG. 6C is a plan view at a depth D3 (third depth) that is positioned between the depth D2 and a second surface shown in FIG. 7A. FIG. 7A is a sectional view taken along line A-A (diagonal direction) in FIG. 6A. FIG. 7B is a sectional view taken along line B-B (opposite side direction) in FIG. 6A.

While only one APD 201 is drawn in FIG. 6A for convenience of illustration, for example, several hundreds of thousands to several millions of APDs 201 are formed in a two-dimensional array in an actual product. One APD 201 corresponds to one pixel.

As shown in FIG. 7A, the sensor substrate 11 has a structure in which a semiconductor layer 300 and a wiring structure 320 are stacked. A surface of the semiconductor layer 300 on a side of the wiring structure 320 will be referred to as a first surface and a surface on an opposite side to the first surface will be referred to as a second surface. The semiconductor layer 300 is made of, for example, silicon. A fixed charge film 310, an insulating film 311, a planarizing film 312, and the like are sequentially stacked on the second surface of the semiconductor layer 300 and a microlens 313 corresponding to each pixel is further provided on top of the stack of films. In other words, the photoelectric conversion apparatus according to the first embodiment has a so-called back-side illuminated structure in which light is incident to the semiconductor layer 300 from the side of the second surface. The second surface may also be referred to as a light incidence surface. In addition, a structure such as that described below can be applied to the light incidence surface. For example, an uneven structure constituted of at least one or more depressed portions or protruded portions is arranged on the second surface that is a light incidence surface. The uneven structure is constructed of silicon that constitutes the semiconductor layer 300 and other members. For example, an insulator such as a silicon oxide film, a silicon oxynitride film, or a silicon nitride film is arranged in a depressed portion provided in the semiconductor layer 300. An interface which is not parallel to the second surface and which has a different refractive index is formed. Since incident light is diffracted due to such a configuration, sensitivity with respect to light in the infrared range can be enhanced.

The fixed charge film 310 is made of a dielectric body having a negative fixed charge and is arranged over the entire second surface of the semiconductor layer 300. A material of the fixed charge film 310 is selected from, for example, hafnium oxide, aluminum oxide, zirconium oxide, titanium oxide, tantalum oxide, and ruthenium oxide and, among these substances, the fixed charge film 310 is preferably made of aluminum oxide or hafnium oxide. The fixed charge film 310 may be made up of a plurality of layers. The insulating film 311 is arranged over the entire second surface on top of the fixed charge film 310. For example, a silicon oxide film, a silicon oxynitride film, or a silicon nitride film can be suitably used as the insulating film 311. The insulating film 311 may be made up of a plurality of layers. Although not illustrated, a filter layer such as a color filter or an infrared light cutoff filter may be provided on the second surface side of the semiconductor layer 300 in addition to the planarizing film 312.

The wiring structure 320 is a structure in which a wiring 321, a contact plug 324 of an anode wiring, a contact plug 326 of a cathode wiring, and the like are arranged inside an insulating layer 329. A surface on a lower side (opposite side to the semiconductor layer 300) of the wiring structure 320 is a bonding surface to the circuit substrate 21 and a plurality of joints 328 (metal bonding) is provided on the bonding surface.

The semiconductor layer 300 includes the first semiconductor region 301, a second semiconductor region 302, a third semiconductor region 303, the fourth semiconductor region 304, a fifth semiconductor region 305, a sixth semiconductor region 306, a seventh semiconductor region 307, and an eighth semiconductor region 308. Each semiconductor region is a region to which impurities have been added by ion implantation or a region to which impurities have been added during fabrication or epitaxial growth of the semiconductor substrate. In this case, the first semiconductor region 301, the fifth semiconductor region 305, the sixth semiconductor region 306, and the seventh semiconductor region 307 are semiconductor regions of a first conductivity type (in the first embodiment, an N type). The second semiconductor region 302, the third semiconductor region 303, the fourth semiconductor region 304, and the eighth semiconductor region 308 are semiconductor regions of a second conductivity type (in the first embodiment, a P type).

The first semiconductor region 301 is a semiconductor region of the first conductivity type (the N type in the first embodiment) which is provided on the first surface of the semiconductor layer 300. As shown in FIG. 6A, the first semiconductor region 301 is formed in a circular shape in a central portion of a pixel (compartment) in a plan view.

The fourth semiconductor region 304 is a semiconductor region of the second conductivity type (the P type in the first embodiment) which is provided on the side of incidence of light (a side closer to the second surface) than the first semiconductor region 301. The fourth semiconductor region 304 is formed in a layer at a predetermined depth so as to vertically divide an epitaxial layer of the first conductivity type in one pixel (compartment). A periphery of the fourth semiconductor region 304 is in contact with a separation portion 331 that encloses the pixel. An epitaxial layer of the first conductivity type on a side of the first surface than the fourth semiconductor region 304 is the fifth semiconductor region 305 and an epitaxial layer of the first conductivity type on a side of the second surface than the fourth semiconductor region 304 is the seventh semiconductor region 307.

The first semiconductor region 301 of the first conductivity type and the fourth semiconductor region 304 of the second conductivity type form an avalanche multiplication portion AM due to a PN junction. A signal charge created inside the seventh semiconductor region 307 due to photoelectric conversion is collected in the avalanche multiplication portion AM. In order to improve sensitivity of the pixel (APD 201), a size of the seventh semiconductor region 307 that corresponds to the sensitivity region is preferably increased.

The sixth semiconductor region 306 is a semiconductor region of the first conductivity type that is formed around the first semiconductor region 301. The sixth semiconductor region 306 is also formed in a circular shape in a plan view. In this case, impurity concentrations of the first semiconductor region 301, the sixth semiconductor region 306, and the fifth semiconductor region 305 are set so as to satisfy a relationship expressed as “impurity concentration of first semiconductor region 301”> “impurity concentration of sixth semiconductor region 306”> “impurity concentration of fifth semiconductor region 305”. In other words, the impurity concentrations are set so that the impurity concentration of the first semiconductor region 301 is highest and the impurity concentration of the sixth semiconductor region 306 is an intermediate concentration between the first semiconductor region 301 and the fifth semiconductor region 305. Accordingly, an electric connection between the cathode and the first semiconductor region 301 (in other words, the APD 201) can be secured. In addition, the sixth semiconductor region 306 also acts as a guard ring for electric field relaxation.

The eighth semiconductor region 308 is an embedded layer of the second conductivity type that is provided so as to constitute a part of the second surface of the semiconductor layer 300. A periphery of the eighth semiconductor region 308 is in contact with the separation portion 331 that encloses the pixel. The eighth semiconductor region 308 is responsible for suppressing noise from the second surface side. In addition, a voltage VL from the anode wiring can be supplied to the eighth semiconductor region 308 via the second semiconductor region 302. In this case, a potential gradient for collecting charges can be formed.

The third semiconductor region 303 that is a connecting portion for electrically connecting the contact plug 324 of the anode wiring and the second semiconductor region 302 of the separation portion 331 to each other is provided on the first surface of the semiconductor layer 300. The second semiconductor region 302 and the third semiconductor region 303 both have the second conductivity type (the P type in the first embodiment). As shown in FIG. 7A, the third semiconductor region 303 is arranged in a portion corresponding to the contact plug 324.

As shown in FIG. 7B, the semiconductor layer 300 is provided with the separation portion 331 that is a separation structure for reducing optical crosstalk (light leakage) between adjacent APDs 201. The APD 201 is arranged on each of the compartments divided by the separation portion 331. In this manner, a plurality of photoelectric conversion elements 102, each including the APD 201, are separated by the separation portion 331. A compartment that corresponds to one pixel has an approximately square shape in a plan view. In other words, the separation portion 331 surrounds one pixel with an approximate quadrangle in a plan view. The contact plug 326 of the cathode wiring formed in the wiring structure 320 is arranged approximately at center of the pixel (compartment) and the contact plug 324 of the anode wiring is arranged at an end of the pixel.

The separation portion 331 suppresses movement of electrons between pixels using a potential barrier. The separation portion 331 also constitutes a part of the second surface of the semiconductor layer 300. The separation portion 331 includes a metal trench 341, an insulating film (insulating separation layer) 351, and the second semiconductor region 302 of the second conductivity type (the P type in the first embodiment). As the metal trench 341, for example, a conductor such as a member that contains tungsten, titanium, tantalum, aluminum, gold, silver, copper, platinum, or a metal compound can be suitably used. The metal trench 341 may be a DTI (Deep Trench Isolation) that penetrates the semiconductor layer. For example, an insulator such as a silicon oxide film, a silicon oxynitride film, or a silicon nitride film can be suitably used as the insulating film 311. The insulating film 351 is provided between the photoelectric conversion element 102 and the metal trench 341. In the first embodiment, the insulating film 351 is provided so as to enclose the metal trench 341. In addition, the second semiconductor region 302 is provided so as to enclose the insulating film 351.

A predetermined potential is applied to the metal trench 341 in order to prevent a state of a pixel boundary portion from becoming unstable. The predetermined potential is favorably a potential equivalent to the voltage VL (first potential) which is supplied to the second semiconductor region 302. This is because a risk of breakdown arises when the potential applied to the metal trench 341 differs from the potential applied to the second semiconductor region 302. Note that a voltage VH (second voltage) is applied to the first semiconductor region 301 that is a semiconductor region of the first conductivity type (the N type in the first embodiment). In other words, a second potential that differs from the first potential that is applied to the semiconductor region of the first conductivity type is applied to the metal trench 341.

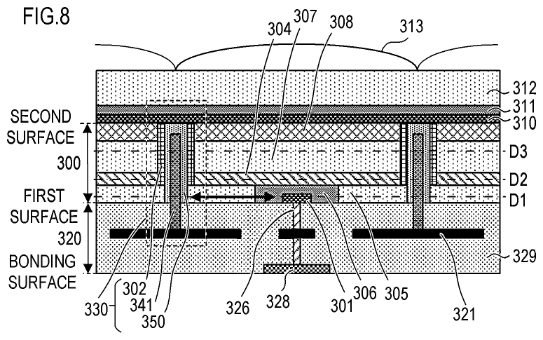

FIG. 8 shows a structure of the sensor substrate 11 of a photoelectric conversion apparatus as a comparative example. FIG. 8 is a sectional view in an opposite side direction of the sensor substrate 11. As shown in FIG. 8, the sensor substrate 11 according to the comparative example and the sensor substrate 11 according to the first embodiment share a same basic configuration.

The metal trench 341 of a separation portion 330 is supplied with a voltage VL (for example, −30 V) in order to prevent breakdown. A voltage VH (for example, 1 V) is supplied to the first semiconductor region 301. In the configuration of the separation portion 330 according to the comparative example, a thickness of an insulating film 350 at a depth D1 and a thickness of the insulating film 350 at a depth D3 are the same and are thin. Therefore, when a large potential difference is created between the metal trench 341 and the first semiconductor region 301, an electric field intensity between the metal trench 341 and the first semiconductor region 301 increases in the configuration of the separation portion 330 according to the comparative example.

In this case, a side of the second surface (the light incidence surface) of the depth D2 is a sensitivity region where a charge in accordance with incident light is created. A side of the first surface (a surface on an opposite side to the second surface) of the depth D2 is a multiplication region where a created charge causes avalanche multiplication. Note that the depth D1 is a same depth as the first semiconductor region 301, the depth D2 is a same depth as the fourth semiconductor region 304, and the depth D3 is a depth that is positioned between the depth D2 and the second surface. The depth D3 is a same depth as the seventh semiconductor region 307.

In the multiplication region, favorably, an electric field intensity of a signal path (an electric field intensity between the first semiconductor region 301 and the fourth semiconductor region 304) is high and an electric field intensity outside of the signal path is low. This is because a high electric field intensity outside of the signal path causes noise. Therefore, at the depth D1 included in the multiplication region, favorably, the electric field intensity between the metal trench 341 and the first semiconductor region 301 that is an electric field intensity outside of the signal path is low.

In consideration thereof, in the first embodiment, the thickness of the insulating film 351 is made thicker than the insulating film 350 according to the comparative example at the depth D1. Specifically, as shown in FIG. 7A, in a direction parallel to the first surface, a thickness T1 of the insulating film 351 at the depth D1 is greater than a thickness T3 of the insulating film 351 at the depth D3. The depth D1 is a depth that is included in the multiplication region and the depth D3 is a depth that is position on a second surface side of the multiplication region and that is included in the sensitivity region. Accordingly, the electric field intensity between the metal trench 341 and the first semiconductor region 301 at the depth D1 can be reduced (the electric field can be relaxed). Note that at least the thickness T1 of the insulating film 351 on a side where the first semiconductor region 301 is present at the depth D1 need only be greater than the thickness T3 of the insulating film 351 at the depth D3. In addition, by not increasing the thickness T3 of the insulating film 351 at the depth D3 unlike the thickness T1 of the insulating film 351 at the depth D1, a size of the sensitivity region is not reduced and a decline in sensitivity can be avoided.

As shown in FIG. 7A, in the first embodiment, the thickness T1 of the insulating film 351 at the depth D1 is greater than the thickness T2 of the insulating film 351 at the depth D2. In addition, as shown in FIG. 7B, the thickness T1 of the insulating film 351 at the depth D1 is greater than a total thickness T4 of the thickness of the third semiconductor region 303 and the thickness of the insulating film 351 at the depth D3.

More preferably, the thickness of the insulating film 351 on a first surface side of a boundary between the fourth semiconductor region 304 and the sixth semiconductor region 306 is greater than the thickness T3 of the insulating film 351 at the depth D3. This is because the electric field intensity between the metal trench 341 and the first semiconductor region 301 can be more effectively reduced in the multiplication region.

In addition, while the thickness of the insulating film 351 decreases the closer to the depth D2 from the depth D1 in FIG. 7A, the thickness of the insulating film 351 is not limited thereto. The thickness T1 of the insulating film 351 at the depth D1 need only be greater than the thickness T3 of the insulating film 351 at the depth D3. In addition, while a boundary between the insulating film 351 and the fifth semiconductor region 305 is shown to have an octagonal shape in a plan view in FIG. 6A, the shape of the boundary is not limited thereto and may be a rectangle or a circle.

In this manner, in the first embodiment, the thickness T1 of the insulating film 351 at the depth D1 is set greater than the thickness T3 of the insulating film 351 at the depth D3. Accordingly, in a configuration in which the separation portion 331 including metal is used, a suppression effect of crosstalk can be enhanced while suppressing noise attributable to an electric field between the separation portion 331 and the APD 201.

### Second Embodiment

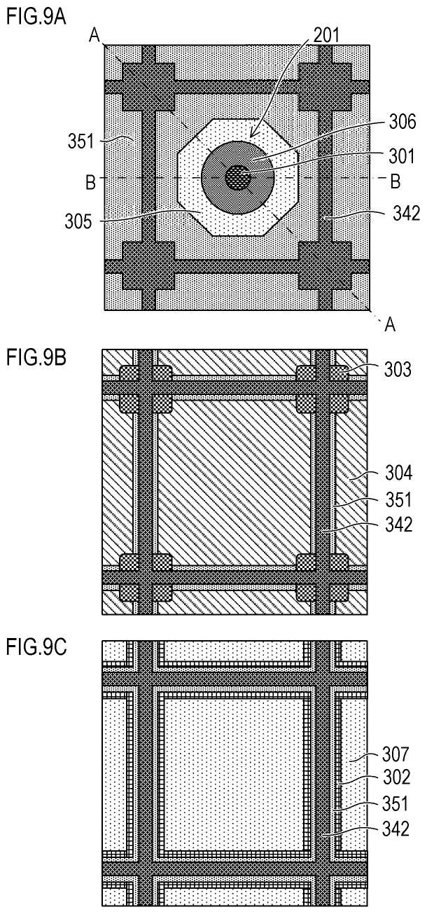

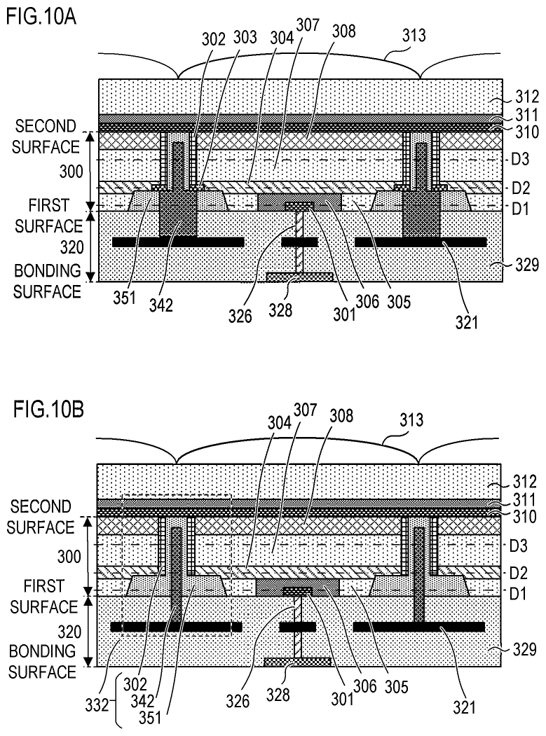

FIGS. 9A to 9C, 10A, and 10B show a structure of the sensor substrate 11 of a photoelectric conversion apparatus according to a second embodiment. FIG. 9A is a plan view at the depth D1 that is a same depth as the first semiconductor region 301 shown in FIG. 10A. FIG. 9B is a plan view at the depth D2 that is a same depth as the fourth semiconductor region 304 shown in FIG. 10A. FIG. 9C is a plan view at the depth D3 that is positioned between the depth D2 and a second surface shown in FIG. 10A. FIG. 10A is a sectional view taken along line A-A (diagonal direction) in FIG. 9A. FIG. 10B is a sectional view taken along line B-B (opposite side direction) in FIG. 9A. Hereafter, components that differ from the first embodiment will be described.

In the first embodiment, an anode electrode (contact plug 324) is provided on the first surface side separately from the metal trench 341. However, since a manufacturing process requires securing a space between the metal trench 341 and the contact plug 324, providing a separate anode electrode may not be suitable for miniaturizing pixels. In consideration thereof, in the second embodiment, a metal trench 342 of a separation portion 332 is made to also function as an anode electrode. Accordingly, since a space between the metal trench 341 and the contact plug 324 need not be secured, pixels can be further miniaturized. In addition, since the anode electrode is formed by a same member and in a same manufacturing process as the metal trench 341, the manufacturing process of the sensor substrate 11 can be further simplified.

As shown in FIG. 10A, at least a part of the metal trench 342 is in contact with the third semiconductor region 303 and an anode potential is supplied to the third semiconductor region 303 via the metal trench 342. As shown in FIG. 10A, an area where the insulating film 351 comes into contact with the third semiconductor region 303 may be secured to a certain extent. This is because a risk of occurrence of noise arises when the area where the metal trench 342 comes into contact with the third semiconductor region 303 is large.

### Third Embodiment

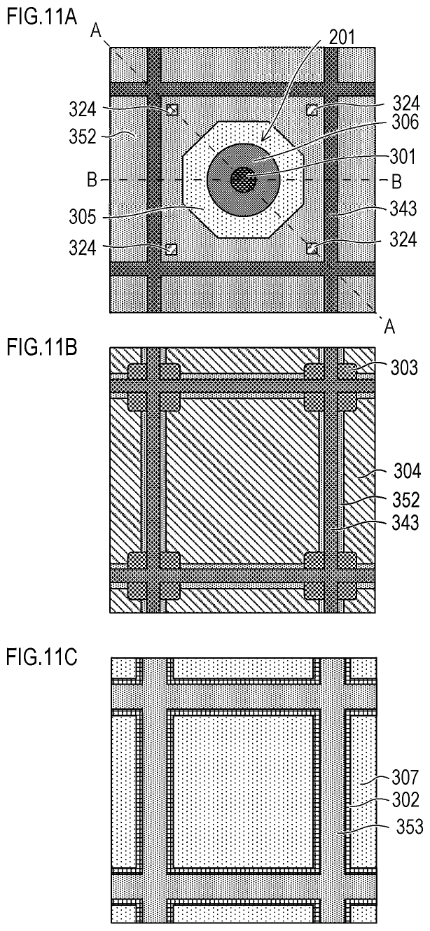

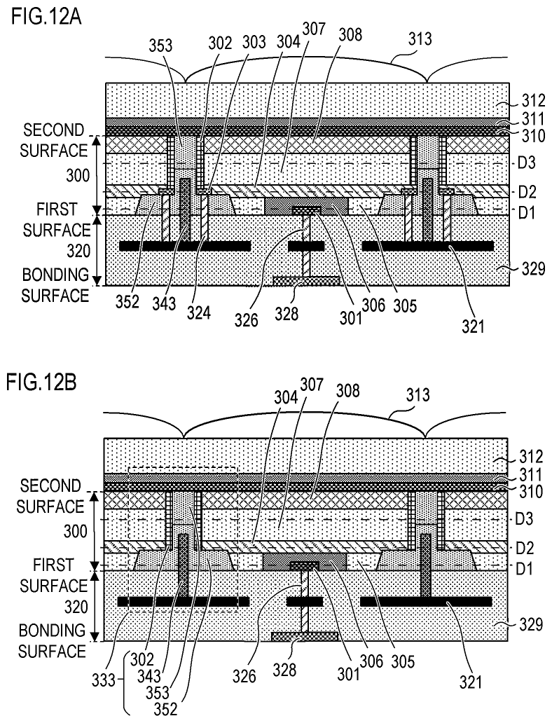

FIGS. 11A to 11C, 12A, and 12B show a structure of the sensor substrate 11 of a photoelectric conversion apparatus according to a third embodiment. FIG. 11A is a plan view at the depth D1 that is a same depth as the first semiconductor region 301 shown in FIG. 12A. FIG. 11B is a plan view at the depth D2 that is a same depth as the fourth semiconductor region 304 shown in FIG. 12A. FIG. 11C is a plan view at the depth D3 that is positioned between the depth D2 and a second surface shown in FIG. 12A. FIG. 12A is a sectional view taken along line A-A (diagonal direction) in FIG. 11A. FIG. 12B is a sectional view taken along line B-B (opposite side direction) in FIG. 11A. Hereafter, components that differ from the first embodiment will be described.

In the first embodiment, the metal trench 341 that penetrates from the insulating layer 329 to a depth of the eighth semiconductor region 308 is provided. Providing the metal trench 341 enables optical crosstalk to be suppressed. However, since incident light also ends up being absorbed by the metal trench 341 to no small extent, there is a risk that sensitivity may decline. In consideration thereof, in the third embodiment, a metal trench 343 that does not penetrate in the depth direction is provided as shown in FIGS. 12A and 12B. Specifically, the metal trench 343 is present at the depth D1 but not at the depth D3. Accordingly, a decline in sensitivity due to the metal trench 343 absorbing incident light can be avoided while suppressing optical crosstalk.

A separation portion 333 includes an insulating film 352 that is a portion on a far side from the second surface (light incidence surface) and an insulating film 353 that is a portion on a near side from the second surface. The metal trench 343 is only provided on the insulating film 352. The insulating film 352 and the insulating film 353 may be made of a same material or made of different materials. The insulating film need not be divided into the insulating film 352 and the insulating film 353.

### Fourth Embodiment

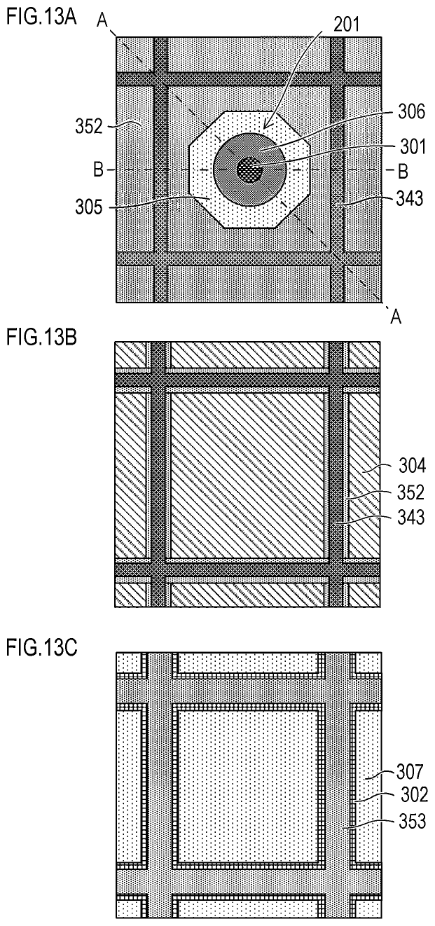

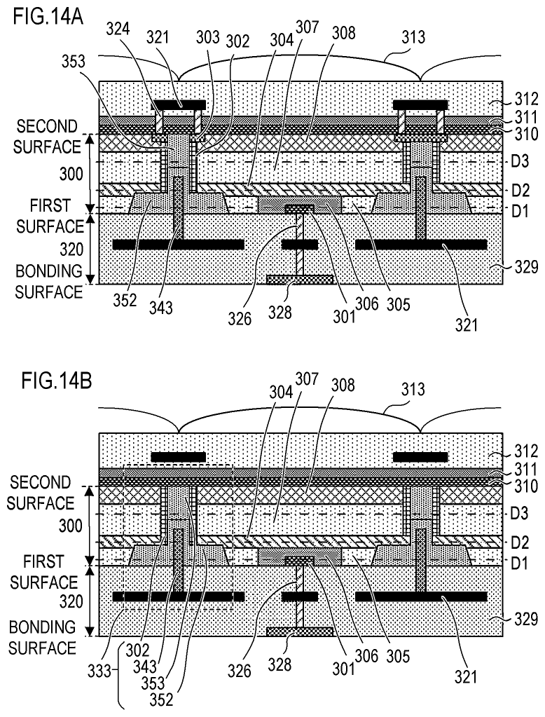

FIGS. 13A to 13C, 14A, and 14B show a structure of the sensor substrate 11 of a photoelectric conversion apparatus according to a fourth embodiment. FIG. 13A is a plan view at the depth D1 that is a same depth as the first semiconductor region 301 shown in FIG. 14A. FIG. 13B is a plan view at the depth D2 that is a same depth as the fourth semiconductor region 304 shown in FIG. 14A. FIG. 13C is a plan view at the depth D3 that is positioned between the depth D2 and a second surface shown in FIG. 14A. FIG. 14A is a sectional view taken along line A-A (diagonal direction) in FIG. 13A. FIG. 14B is a sectional view taken along line B-B (opposite side direction) in FIG. 13A. Hereafter, components that differ from the third embodiment will be described.

In the third embodiment, an anode electrode (contact plug 324) is provided on the first surface side. However, since a manufacturing process requires securing a space between the metal trench 343 and the contact plug 324, providing an anode electrode on the first surface side may not be suitable for miniaturizing pixels. In consideration thereof, in the fourth embodiment, the contact plug 324 is not provided on the first surface side but provided on the second surface side. Accordingly, since a space between the metal trench 343 and the contact plug 324 need not be secured, pixels can be further miniaturized. Note that the third semiconductor region 303 is supplied with an anode potential via the wiring 321 and the contact plug 324 provided on the second surface side and the metal trench 343 is supplied with an anode potential via the wiring 321 provided on the first surface side.

### Fifth Embodiment

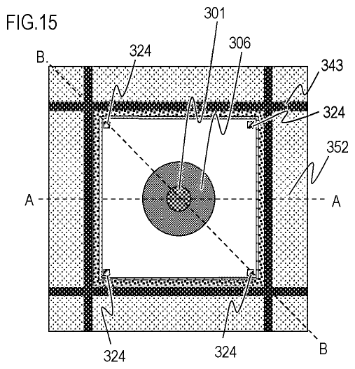

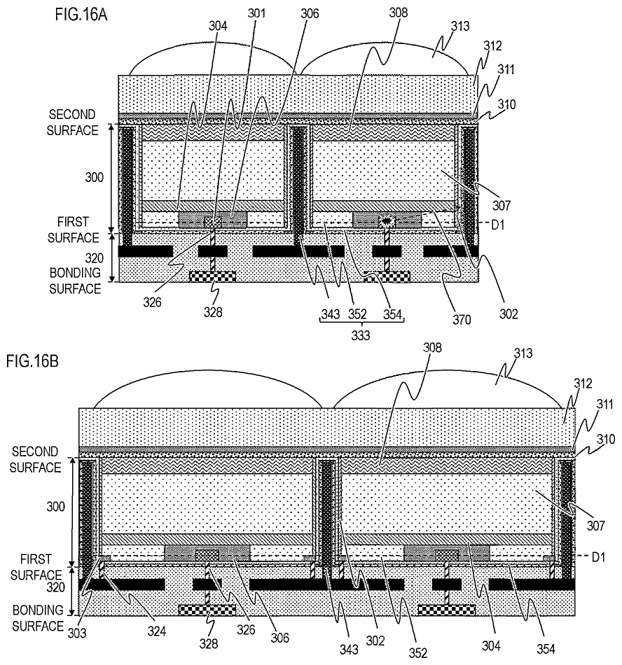

FIGS. 15, 16A, and 16B show a structure of the sensor substrate 11 of a photoelectric conversion apparatus according to a fifth embodiment. FIG. 15 is a plan view at the depth D1 that is a same depth as the first semiconductor region 301 shown in FIG. 16A. FIG. 16B is a sectional view taken along line B-B (opposite side direction) in FIG. 15.

In the fifth embodiment, the separation portion 333 is constituted of the metal trench 343, the insulating film 352, and an optical film 354.

As materials thereof, for example, the insulating film 352 is a silicon oxide film with a refractive index of 1.46, the optical film 354 is a silicon nitride film with a refractive index of 2.02, and the metal trench 343 is constituted of tungsten with a reflectance of 35% and titanium nitride with a reflectance of 50%. However, these materials are merely an example and other materials described earlier can also be used.

The material of the optical film 354 need only be an insulating film with a higher refractive index than the insulating film 352 and, for example, a silicon oxynitride film, aluminum oxide, or the like can be used besides the silicon nitride film described earlier. More favorably, the material has low transmittivity and examples in this case include titanium nitride and tantalum compounds.

The insulating film 352 extends to the wiring structure 320 together with the metal trench 343 and is arranged parallel to the first surface.

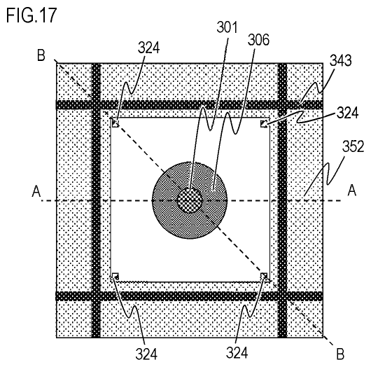

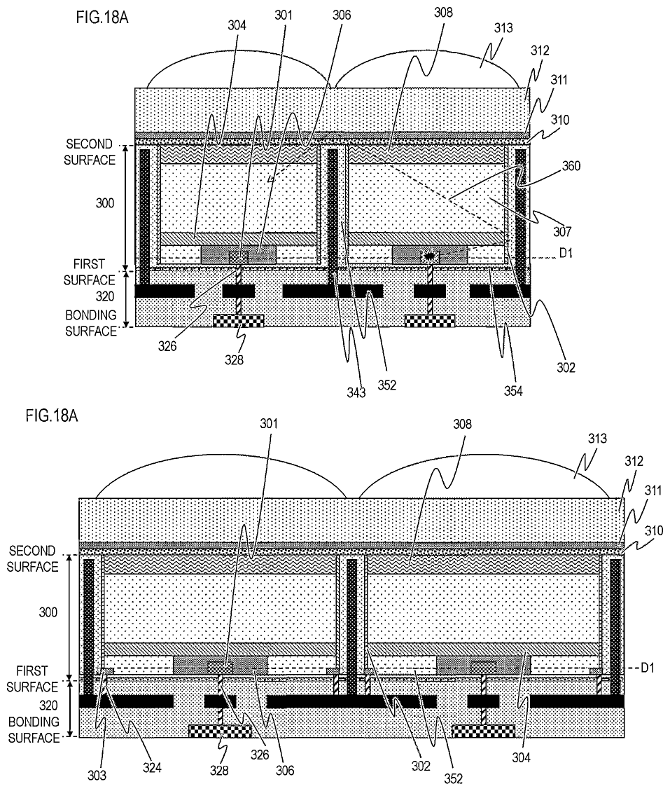

FIGS. 17, 18A, and 18B show a structure of a comparative example for illustrating an effect of the fifth embodiment. FIG. 17 is a plan view at the depth D1 that is a same depth as the first semiconductor region 301 shown in FIG. 18A. FIG. 18B is a sectional view taken along line B-B (opposite side direction) in FIG. 17. The comparative example differs from the fifth embodiment in that the optical film 354 is not included in the separation portion 333. Hereinafter, an additional effect of “suppressing leaking of avalanche emission light into adjacent pixels” that is produced by the fifth embodiment will be described using the comparative example.

In FIG. 17, a location where avalanche emission occurs is a multiplication region in a vicinity of the first semiconductor region 301. A light emission phenomenon occurs when a part of the large amount of generated electrons recombine with holes.

The comparative example differs from the fifth embodiment in that the optical film 354 is not included in the separation portion 333. Therefore, in the comparative example, as indicated by an arrow 360 in FIG. 18A, while a part of the avalanche emission light is absorbed by the metal trench 343, another part of the avalanche emission light travels along a path depicted by a dotted line after being reflected, leaks into an adjacent pixel, and becomes a false signal of the adjacent pixel.

By contrast, in the fifth embodiment, as indicated by an arrow 370 in FIG. 16A, since the optical film 354 prevents light of avalanche emission from being reflected by the metal trench 343, an amount of leakage into the adjacent pixel can be suppressed.

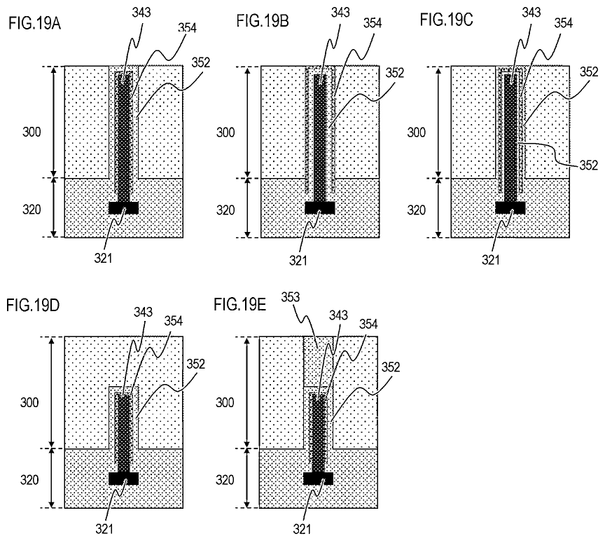

FIGS. 19A to 19D, FIGS. 20A to 20C, FIGS. 21A to 21D, and FIGS. 22A to 22C show structural variations of the separation portion 333.

FIGS. 19A, 19B, and 19C show a positional relationship of the insulating film 352 and the optical film 354 with respect to the metal trench 343. A desired effect can be produced regardless of the optical film 354 being positioned on an outer side of the insulating film 352 with respect to the metal trench 343 (FIG. 19A), the optical film 354 being positioned on an inner side of the insulating film 352 (FIG. 19B), and the optical film 354 being sandwiched by the insulating film 352 from inner and outer sides (FIG. 19C). In addition, as shown in FIG. 19D, providing the optical film 354 even in a part of the depth of the semiconductor layer produces an effect of preventing reflection. Furthermore, as shown in FIG. 19E, connecting the remaining semiconductor layer close to the second surface by the insulating film 353 enables an effect of suppressing a decline in sensitivity as in the third embodiment to be produced.

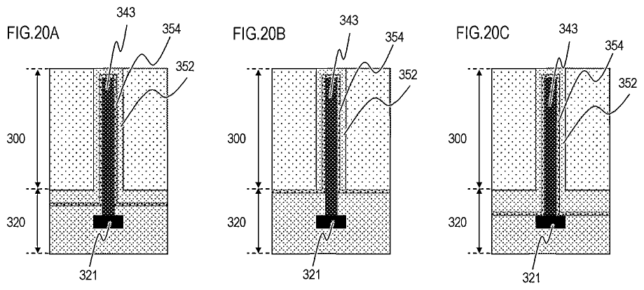

FIGS. 20A, 20B, and 20C show structural variations in a case where, after the optical film 354 extends to the wiring structure 320, the optical film 354 remains as a film parallel to the first surface.

Since light of an avalanche emission spreads in all directions, leakage into an adjacent pixel can be further suppressed by addressing not only the reflection from the metal trench 343 but also the reflection from the wiring 321. In this case, as shown in FIGS. 20A, 20B, and 20C, the optical film 354 may be pasted to a surface of the semiconductor layer, pasted to the wiring 321, or positioned between the surface of the semiconductor layer and the wiring 321. Furthermore, the structural variations in FIGS. 20A, 20B, and 20C can also be combined with the structural variations in each of FIGS. 19A to 19E.

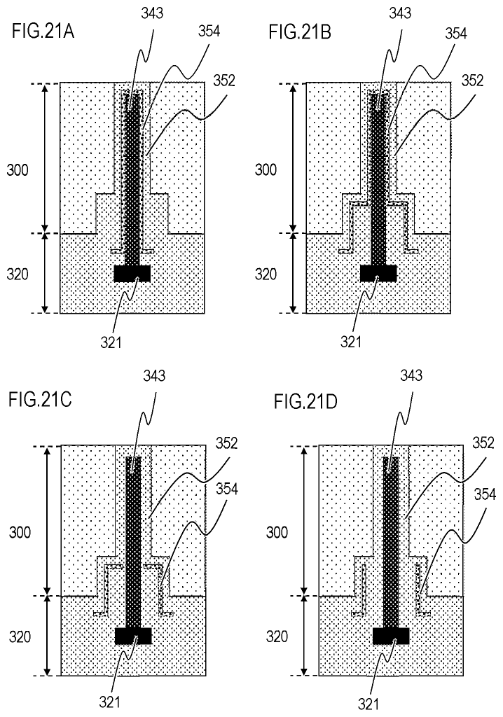

FIGS. 21A, 21B, 21C, and 21D show structural variations of the optical film 354 in a case where the separation portion 333 has a thickness in two stages in the depth direction.

In the case of the separation portion 333 with a thickness in two stages, as long as the optical film 354 is present on at least a side wall of the trench in the first stage, the additional effect of “suppressing leaking of avalanche emission light into adjacent pixels” that is the objective can be produced. However, many variations with respect to a position of the optical film 354 in the separation portion 333 may be adopted depending on a manufacturing sequence and examples of such variations will be described below.

FIG. 21A represents a structure in which the optical film 354 is in contact with the metal trench 343 all the way to the wiring structure 320. Such a structure is created by embedding trenches with different thicknesses into the insulating film 352 and subsequently forming a new trench in the insulating film 352 to embed the optical film 354 and the metal trench 343. FIG. 21B represents a structure in which the optical film 354 is coated so as to follow a shape of the separation portion 333. Such a structure is created by forming a trench with a thickness in two stages, embedding the insulating film 352 and the optical film 354 by a film with high coverage, once again embedding with the insulating film 352, and machining the metal trench 343. FIG. 21C represents a structure in which the optical film 354 is coated so as to only follow a trench shape of the first stage of the separation portion 333. Such a structure is created by forming a trench of the first stage, embedding the insulating film 352 and the optical film 354 by a film with high coverage, subsequently forming the trench of the second stage, and embedding with the insulating film 352 and the metal trench 343. FIG. 21D represents a structure in which the optical film 354 is coated only on a side wall of the trench of the first stage of the separation portion 333. Such a structure is created by forming a trench of the first stage, embedding the insulating film 352 and the optical film 354 by a film with high coverage, removing a nitride film in a bottom portion of the trench by etching back the nitride film, forming the trench of the second stage, and embedding with the insulating film 352 and the metal trench 343. Furthermore, the structural variations in FIGS. 21A, 21B, 21C, and 21D can also be combined with the structural variations in each of FIGS. 19A to 19E and FIGS. 20A to 20C.

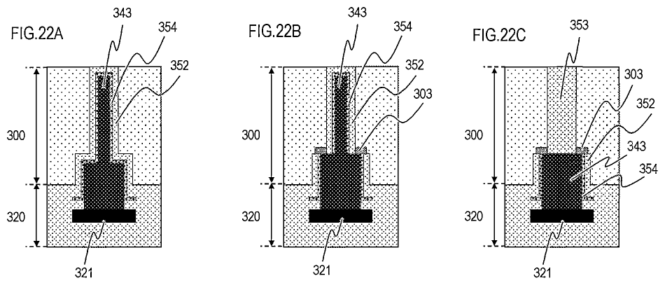

FIGS. 22A, 22B, and 22C show structural variations of the optical film 354 and the metal trench 343 in a case where the separation portion 333 has a thickness in two stages in the depth direction and the thickness of the metal trench 343 is greater in the first stage than in the second stage.

In the case of the separation portion 333 with a thickness in two stages, the fact that the additional effect of “suppressing leaking of avalanche emission light into adjacent pixels” that is the objective can be produced as long as the optical film 354 is present on at least a side wall of the trench in the first stage remains the same even when the thickness of the metal trench 343 changes. However, given that increasing the thickness of the metal trench 343 in the first stage enables an additional effect of directly applying a potential from the metal trench 343 to the semiconductor layer 300 to be produced, examples will be described below.

FIG. 22A represents a structure in which the optical film 354 is coated so as to follow a shape of the separation portion 333. A manufacturing process can be simplified as compared to FIG. 21B and such a structure is created by forming a trench with a thickness in two stages, embedding the insulating film 352 and the optical film 354 by a film with high coverage, and embedding the metal trench 343. FIG. 22B represents a structure that enables the metal trench 343 to connect to the semiconductor layer 300 and apply a potential at a bottom of the trench in the first stage. Until the middle of the manufacturing process, a trench with a thickness in two stages is formed and the insulating film 352 and the optical film 354 are subsequently embedded by a film with high coverage as shown in FIG. 22A. Subsequently, after reaching a silicon layer by etching back, the structure can be created by forming the third semiconductor region 303 by ion implantation such as self-alignment and embedding the metal trench 343. FIG. 22C represents a structure in which the trench from the first surface is limited to the trench of the first stage and the remaining semiconductor layer close to the second surface is connected by the insulating film 353 in order to also enable an effect of suppressing a decline in sensitivity as in the third embodiment to be produced. First, after forming the trench with the thickness of the first stage, the insulating film 352 and the optical film 354 are embedded with a film with high coverage, a silicon layer is subsequently reached by etching back, and the third semiconductor region 303 is formed by ion implantation such as self-alignment. Next, a trench is formed so as to connect the remaining semiconductor layer from the second surface and embedding is performed with the insulating film 353. In doing so, by making the trench from the second surface narrow, the third semiconductor region 303 can be retained and a potential can be applied. Furthermore, the structural variations in FIGS. 22A, 22B, and 22C can also be combined with the structural variations in each of FIGS. 19A to 19E, FIGS. 20A to 20C, and FIGS. 21A to 21D.

### Sixth Embodiment

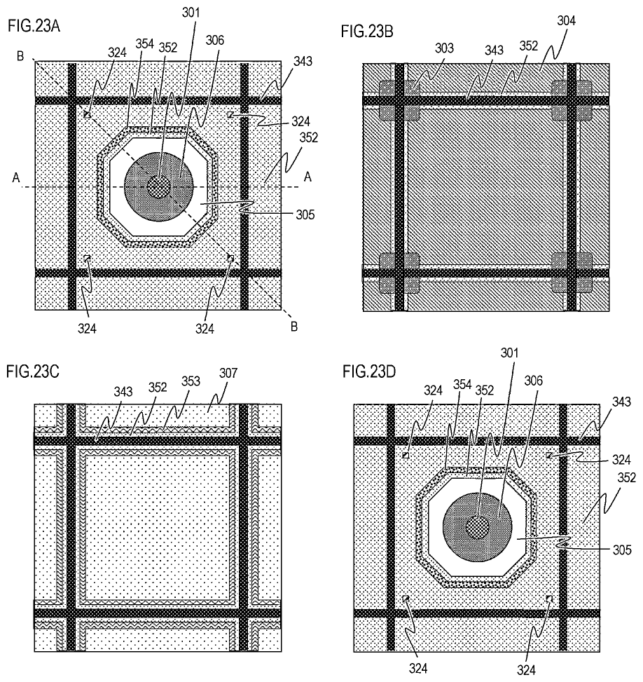

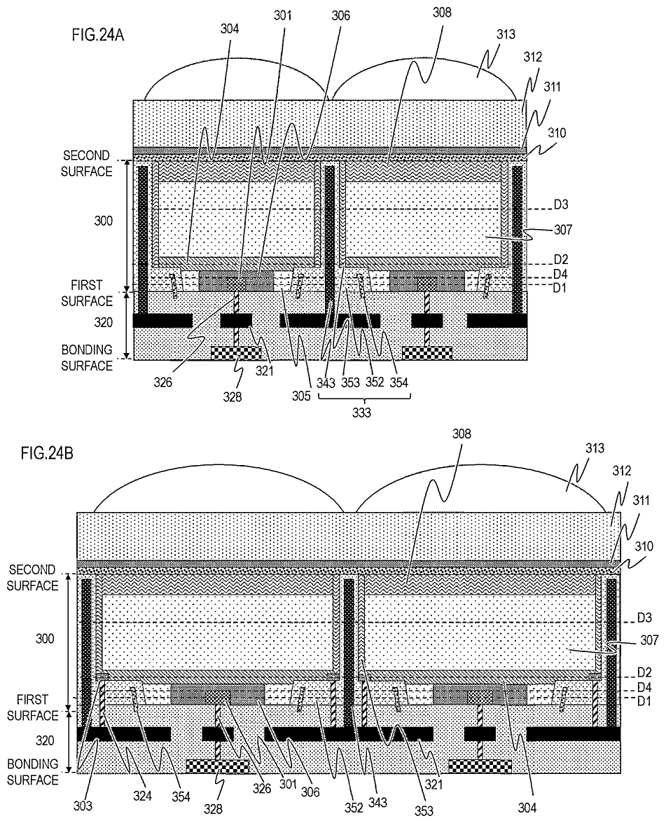

FIGS. 23A to 23D, 24A, and 24B show a structure of the sensor substrate 11 of a photoelectric conversion apparatus according to a sixth embodiment. FIG. 23A is a plan view at the depth D1 that is a same depth as the first semiconductor region 301 shown in FIG. 24A. FIG. 23B is a plan view at the depth D2 that is a same depth as the fourth semiconductor region 304 shown in FIG. 24A. FIG. 23C is a plan view at the depth D3 that is positioned between the depth D2 and a second surface shown in FIG. 24A. FIG. 23D is a plan view at a depth D4 at which the optical film 354 in a bottom portion of the trench of the first stage shown in FIG. 24A is present. FIG. 24A is a sectional view taken along line A-A (diagonal direction) in FIG. 23A. FIG. 24B is a sectional view taken along line B-B (opposite side direction) in FIG. 23A. Hereafter, components that differ from the fifth embodiment will be described.

In the case of the separation portion 333 with a thickness in two stages, the fact that the additional effect of “suppressing leaking of avalanche emission light into adjacent pixels” that is the objective can be produced as long as the optical film 354 is present on at least a side wall of the trench in the first stage remains the same even in the present embodiment.

However, when etching a contact plug, since etching rates differ between the optical film 354 and the insulating film 352, rate control is expected to become difficult. In the present embodiment, a configuration is adopted in which the optical film 354 is absent from both machining of the contact plug 324 of the anode wiring and machining of the contact plug 326 of the cathode wiring. Therefore, the etching rate of the contact plugs can be set based on a constant rate condition of only the insulating film 352 and the difficulty of rate control can be reduced.

### Seventh Embodiment

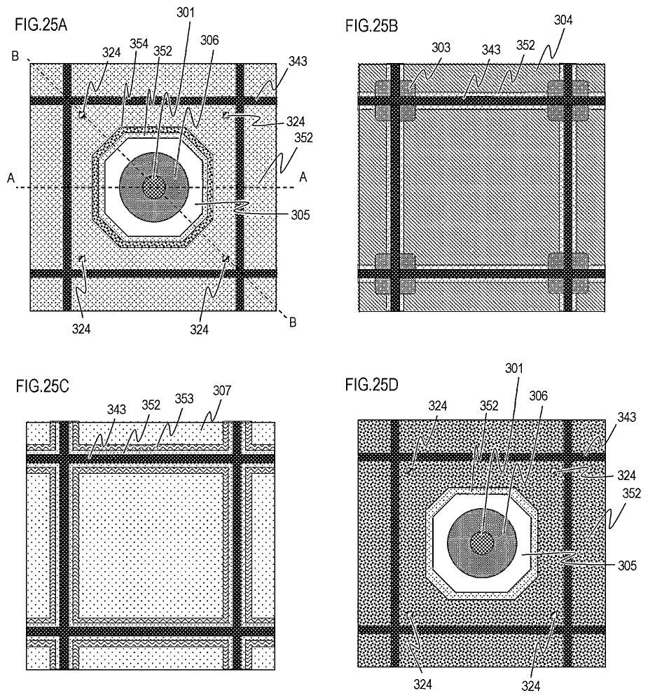

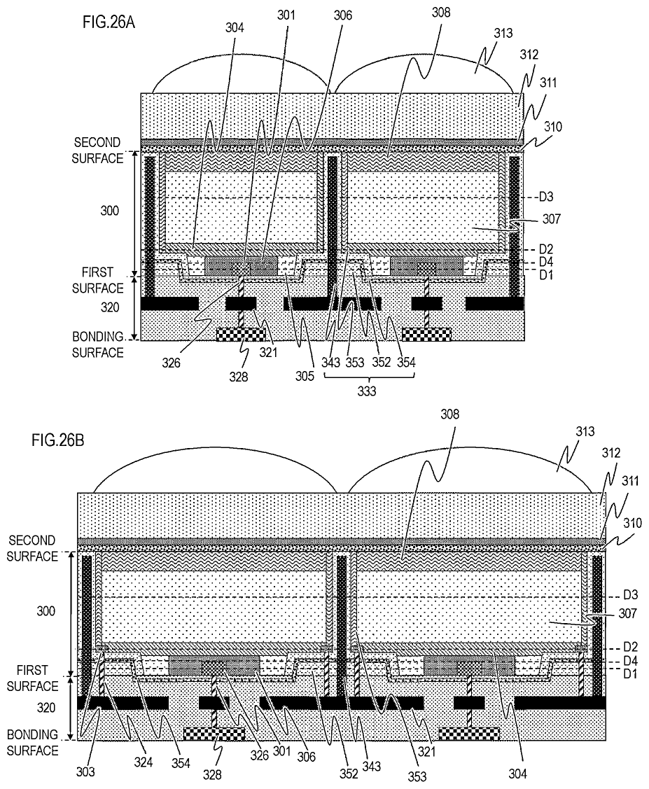

FIGS. 25A to 25D, 26A, and 26B show a structure of the sensor substrate 11 of a photoelectric conversion apparatus according to a seventh embodiment. FIG. 25A is a plan view at the depth D1 that is a same depth as the first semiconductor region 301 shown in FIG. 26A. FIG. 25B is a plan view at the depth D2 that is a same depth as the fourth semiconductor region 304 shown in FIG. 26A. FIG. 25C is a plan view at the depth D3 that is positioned between the depth D2 and a second surface shown in FIG. 26A. FIG. 25D is a plan view at the depth D4 at which the optical film 354 in a bottom portion of the trench of the first stage shown in FIG. 26A is present. FIG. 26A is a sectional view taken along line A-A (diagonal direction) in FIG. 25A. FIG. 26B is a sectional view taken along line B-B (opposite side direction) in FIG. 25A. Hereafter, components that differ from the sixth embodiment will be described.

The sixth embodiment is certainly optimal in terms of enabling a difficulty in rate control to be lowered when etching contact plugs. However, there is room for improvement in terms of also addressing reflections of avalanche emission light from the wiring 321 as described earlier with reference to the structural variation in FIGS. 20A to 20C. In consideration thereof, the present embodiment is conceivable as a workaround.

In the present embodiment, a manufacturing method such as performing isotropic film deposition is used. Accordingly, a structure is realized in which a film configuration from the optical film 354 to the semiconductor layer is the same in both machining of the contact plug 324 of the anode wiring and machining of the contact plug 326 of the cathode wiring. Therefore, the optical film 354 can be used as an etching stopper film to stop a first etching at the optical film 354 and make the semiconductor layer conductive in a second etching. As a result, both addressing the reflection from the wiring 321 and lowering the difficulty of rate control during etching can be satisfied.

### Eighth Embodiment

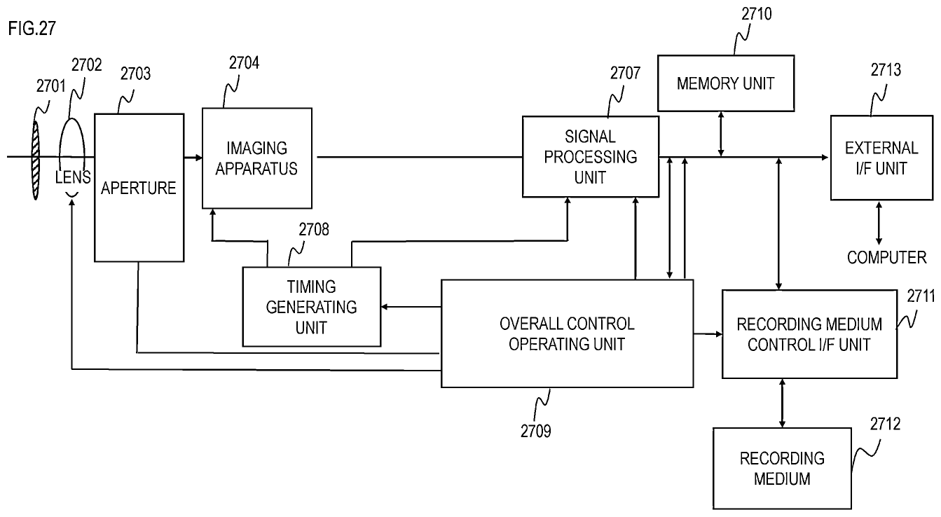

A photoelectric conversion system according to the present embodiment will be described with reference to FIG. 27. FIG. 27 is a block diagram showing a schematic configuration of the photoelectric conversion system according to the present embodiment.

The photoelectric conversion apparatuses described in the first to seventh embodiments can be applied to various photoelectric conversion systems. Each of the photoelectric conversion systems includes at least the photoelectric conversion apparatuses according to any of the embodiments described above and a signal processing portion that processes signals output from the photoelectric conversion apparatus. Examples of devices to which such a photoelectric conversion system can be applied include a digital still camera, a digital camcorder, a monitoring camera, a copier, a facsimile, a mobile phone, a vehicle-mounted camera, an observation satellite, a sensor, and a measuring instrument. In addition, camera modules provided with an optical system such as a lens and an imaging apparatus are also included in devices to which a photoelectric conversion system is applied. FIG. 27 illustrates a block diagram of a digital still camera as an example of such devices.

The photoelectric conversion system illustrated in FIG. 27 has an imaging apparatus 2704 as an example of the photoelectric conversion apparatus and a lens 2702 that causes an optical image of a subject to be formed on the imaging apparatus 2704. In addition, the photoelectric conversion system has an aperture 2703 for making a light amount that passes through the lens 2702 variable and a barrier 2701 for protecting the lens 2702. The lens 2702 and the aperture 2703 are optical systems for collecting light to the imaging apparatus 2704. The imaging apparatus 2704 is the photoelectric conversion apparatus (imaging apparatus) according to any of the embodiments described above and converts an optical image having been formed by the lens 2702 into an electric signal.

The photoelectric conversion system also has a signal processing portion 2707 which is an image generating portion for generating an image by processing an output signal that is output from the imaging apparatus 2704. The signal processing portion 2707 performs operations in which the output signal is subjected to various corrections and compression when necessary and image data is output. The signal processing portion 2707 may be formed on a semiconductor substrate provided with the imaging apparatus 2704 or formed on a semiconductor substrate that is separate from the imaging apparatus 2704. In addition, the imaging apparatus 2704 and the signal processing portion 2707 may be formed on a same semiconductor substrate.

The photoelectric conversion system further has a memory portion 2710 for temporarily storing image data and an external interface portion (an external I/F portion) 2713 for communicating with an external computer or the like. Furthermore, the photoelectric conversion system has a recording medium 2712 such as a semiconductor memory for recording or reading imaging data and a recording medium control interface portion (a recording medium control I/F portion) 2711 for performing recording or reading with respect to the recording medium 2712. The recording medium 2712 may be built into the photoelectric conversion system or may be attachable to and detachable from the photoelectric conversion system.

Furthermore, the photoelectric conversion system has an overall control operating portion 2709 that performs various arithmetic operations and controls the entire digital still camera and a timing generating portion 2708 that outputs various timing signals to the imaging apparatus 2704 and the signal processing portion 2707. In this case, the timing signals and the like may be input from outside and the photoelectric conversion system need at least have the imaging apparatus 2704 and the signal processing portion 2707 that processes an output signal that is output from the imaging apparatus 2704.

The imaging apparatus 2704 outputs an imaging signal to the signal processing portion 2707. The signal processing portion 2707 performs predetermined signal processing on the imaging signal output from the imaging apparatus 2704 and outputs image data. The signal processing portion 2707 generates an image using the imaging signal.

As described above, according to the present embodiment, a photoelectric conversion system to which the photoelectric conversion apparatus (imaging apparatus) according to any of the embodiments described above is applied can be realized.

### Ninth Embodiment

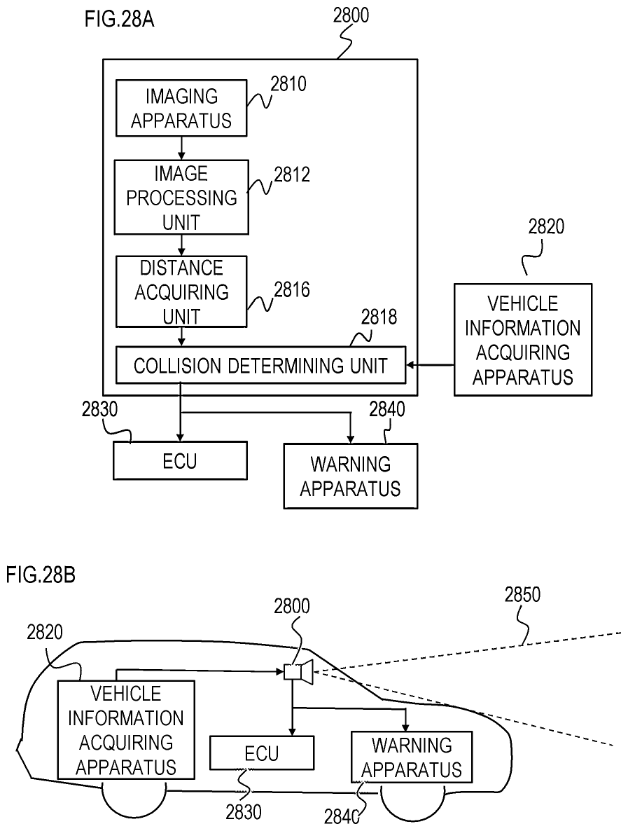

A photoelectric conversion system and a moving body according to the present embodiment will be described with reference to FIGS. 28A and 28B. FIG. 28A is a diagram showing a configuration of the photoelectric conversion system according to the present embodiment and FIG. 28B is a diagram showing a configuration of the moving body according to the present embodiment.

FIG. 28A shows an example of a photoelectric conversion system related to a vehicle-mounted camera. A photoelectric conversion system 2800 includes an imaging apparatus 2810 to which the photoelectric conversion apparatus (imaging apparatus) described in any one of the embodiments described above is applied. The photoelectric conversion system 2800 has an image processing unit 2812 that performs image processing on a plurality of pieces of image data acquired by the imaging apparatus 2810. In addition, the photoelectric conversion system 2800 has a distance acquiring unit 2816 that calculates a distance to an object and a collision determining unit 2818 that determines whether or not there is a possibility of a collision based on the calculated distance. In this case, the distance acquiring unit 2816 may acquire information on the distance to the object based on a ToF (Time of Flight) or may acquire distance information using parallax information or the like. Furthermore, the distance acquiring unit 2816 may acquire distance information by combining ranging according to ToF and ranging based on a phase difference between pixels. In other words, distance information is information related to a parallax, a defocus amount, a distance to the object, or the like. The collision determining unit 2818 may determine a possibility of a collision using any of these pieces of distance information. The distance information acquiring means may be realized by exclusively-designed hardware or may be realized by a software module. Alternatively, the distance information acquiring means may be realized by an FPGA (Field Programmable Gate Array), an ASIC (Application Specific Integrated Circuit), or the like, or a combination thereof.

The photoelectric conversion system 2800 is connected to a vehicle information acquiring apparatus 2820 and is capable of acquiring vehicle information such as a vehicle speed, a yaw rate, and a steering angle. In addition, an ECU 2830 which is a control apparatus that outputs a control signal causing a vehicle to generate a braking force based on a determination result of the collision determining unit 2818 is connected to the photoelectric conversion system 2800. Furthermore, the photoelectric conversion system 2800 is also connected to a warning apparatus 2840 that issues a warning to a driver based on a determination result of the collision determining unit 2818. For example, when it is found that the possibility of a collision is high as a determination result of the collision determining unit 2818, the ECU 2830 performs vehicle control involving applying the brakes, releasing the gas pedal, suppressing engine output, or the like to avoid a collision and/or reduce damage. The warning apparatus 2840 issues a warning to a user by sounding an alarm, displaying warning information on a screen of a car navigation system or the like, vibrating a seat belt or a steering wheel, or the like.

In the present embodiment, an image of a periphery of the vehicle such as the front or the rear of the vehicle is picked up by the photoelectric conversion system 2800. FIG. 28B shows the photoelectric conversion system when imaging of the front of the vehicle (an imaging range 2850) is performed. The vehicle information acquiring apparatus 2820 sends an instruction to the photoelectric conversion system 2800 or the imaging apparatus 2810. According to such a configuration, accuracy of ranging can be further improved.

While an example of controlling a vehicle so as to prevent a collision with another vehicle has been described above, the photoelectric conversion system can also be applied to controlling automated driving so that the vehicle follows another vehicle, controlling automated driving so that the vehicle stays within a lane, and the like. In addition, the photoelectric conversion system is not limited to a vehicle such as an automobile and can also be applied to a moving body (moving apparatus) such as a ship, an airplane, or an industrial robot. The moving body includes one of or both of a driving force generating unit that generates a driving force mainly used for movement of the moving body and a rotating member that is mainly used for movement of the moving body. The driving force generating unit can be an engine, a motor, or the like. The rotating member can be a tire, a wheel, a screw of a ship, a propeller of a flight vehicle, or the like. Moreover, besides moving bodies, the photoelectric conversion system can be applied to a wide variety of apparatuses that utilize object recognition such as an intelligent transportation system (ITS).

### Tenth Embodiment

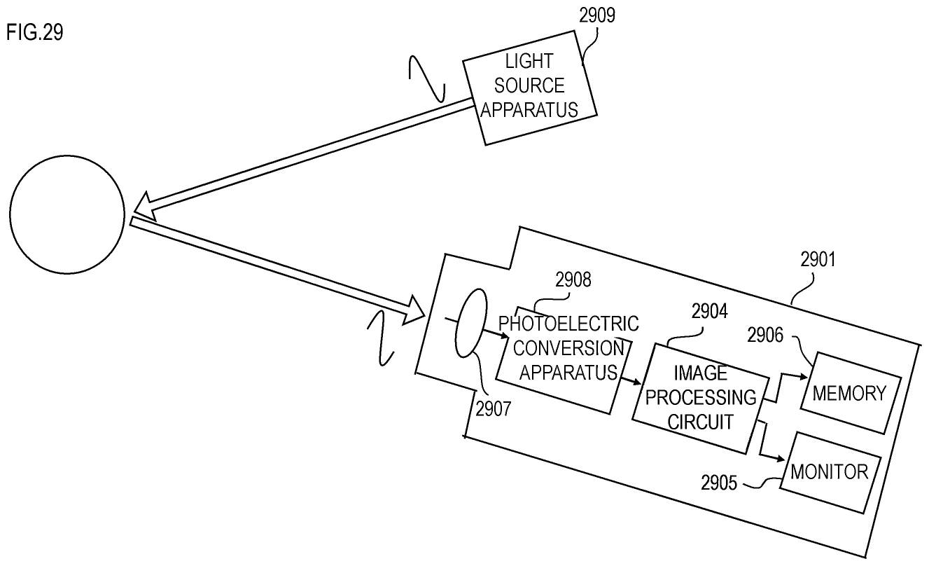

A photoelectric conversion system according to the present embodiment will be described with reference to FIG. 29. FIG. 29 is a block diagram showing a configuration example of a distance image sensor that is the photoelectric conversion system according to the present embodiment.

As shown in FIG. 29, a distance image sensor 2901 is configured to include an optical system 2907, a photoelectric conversion apparatus 2908, an image processing circuit 2904, a monitor 2905, and a memory 2906. In addition, the distance image sensor 2901 is capable of acquiring a distance image in accordance with a distance to a subject by receiving light (modulated light or pulsed light) emitted toward the subject from a light source apparatus 2909 and reflected by a surface of the subject.

The optical system 2907 is configured with one or a plurality of lenses and guides image light (incident light) from the subject to the photoelectric conversion apparatus 2908 and forms an image on a light-receiving surface (a sensor unit) of the photoelectric conversion apparatus 2908.

The image processing circuit 2904 performs image processing for constructing a distance image based on the distance signal supplied from the photoelectric conversion apparatus 2908. In addition, a distance image (image data) obtained by the image processing is supplied to and displayed by the monitor 605 or supplied to and stored (recorded) in the memory 2906.

With the distance image sensor 2901 configured as described above, applying one of the photoelectric conversion apparatuses described above enables, for example, a more accurate distance image to be acquired due to an improvement in ranging accuracy.

### Eleventh Embodiment

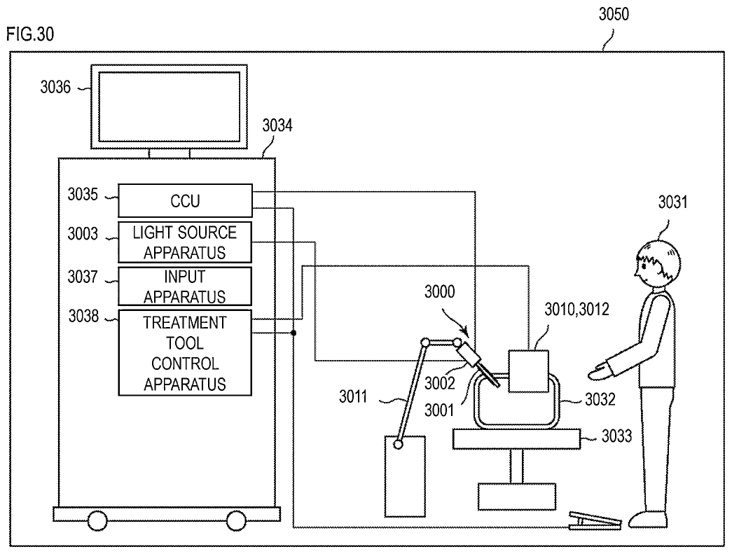

A photoelectric conversion system according to the present embodiment will be described with reference to FIG. 30. FIG. 30 is a diagram showing an example of a schematic configuration of an endoscopic surgery system that is the photoelectric conversion system according to the present embodiment.

FIG. 30 illustrates a situation where a technician (a physician) 3031 is using an endoscopic surgery system 3050 to operate on a patient 3032 on a patient bed 3033. As illustrated, the endoscopic surgery system 3050 is constituted of an endoscope 3000, a surgical instrument 3010, and a cart 3034 mounted with various apparatuses for an endoscopic surgery.

The endoscope 3000 is constituted of a lens barrel 3001 of which a region with a predetermined length from a distal end is to be inserted into a body cavity of the patient 3032 and a camera head 3002 connected to a base end of the lens barrel 3001. While the illustrated example features the endoscope 3000 being configured as a so-called rigid scope having a rigid lens barrel 3001, alternatively, the endoscope 3000 may be configured as a so-called flexible scope having a flexible lens barrel.

An opening into which an objective lens is fitted is provided at the distal end of the lens barrel 3001. A light source apparatus 3003 is connected to the endoscope 3000, and light generated by the light source apparatus 3003 is guided to the distal end of the lens barrel 3001 by a light guide provided so as to extend inside the lens barrel and emitted toward an observation object inside a body cavity of the patient 3032 via the objective lens. It should be noted that the endoscope 3000 may be a forward-viewing endoscope, an oblique-viewing endoscope, or a side-viewing endoscope.

An optical system and a photoelectric conversion apparatus are provided inside the camera head 3002 and reflected light (observation light) from the observation object is collected to the photoelectric conversion apparatus by the optical system. The observation light is photoelectrically converted by the photoelectric conversion apparatus and an electric signal corresponding to the observation light or, in other words, an image signal corresponding to an observed image is generated. As the photoelectric conversion apparatus, the photoelectric conversion apparatus according to any one of the embodiments described above can be used. The image signal is transmitted to a Camera Control Unit (CCU) 3035 as RAW data.

The CCU 3035 is constituted of a CPU (Central Processing Unit), a GPU (Graphics Processing Unit), or the like and comprehensively controls operations of the endoscope 3000 and a display apparatus 3036. In addition, the CCU 3035 receives an image signal from the camera head 3002 and subjects the image signal to various kinds of image processing for displaying an image based on the image signal such as development processing (demosaicing).

Under control exerted by the CCU 3035, the display apparatus 3036 displays an image based on the image signal subjected to image processing by the CCU 3035. The light source apparatus 3003 is constituted of a light source such as an LED (Light-Emitting Diode) and supplies the endoscope 3000 with irradiation light used when photographing a surgical site or the like.

An input apparatus 3037 is an input interface with respect to the endoscopic surgery system 3050. A user can input various kinds of information and input instructions to the endoscopic surgery system 3050 via the input apparatus 3037.

A treatment tool control apparatus 3038 controls drive of an energy treatment tool 3012 for cauterizing or incising tissue, sealing a blood vessel, or the like. The light source apparatus 3003 that supplies the endoscope 3000 with irradiation light when photographing a surgical site can be constituted of a white light source constituted of an LED, a laser light source, or a combination thereof. When the white light source is constituted of a combination of RGB laser light sources, since output intensity and an output timing of each color (each wavelength) can be controlled with high accuracy, white balance of a captured image can be adjusted in the light source apparatus 3003. In addition, in this case, an image corresponding to each of RGB can be captured in a time-divided manner by having an observation object be irradiated with laser light from each of the RGB laser light sources in a time-divided manner and controlling drive of an imaging element of the camera head 3002 in synchronization with the irradiation timing. According to this method, a color image can be obtained without having to provide the imaging element with a color filter.

In addition, drive of the light source apparatus 3003 may be controlled such that intensity of output light changes at predetermined intervals. By controlling drive of imaging elements of the camera head 3002 in synchronization with a timing at which the intensity of light changes to acquire images in a time-divided manner and compositing the images, an image with a high dynamic range that is free of so-called blocked-up shadows and blown-out highlights can be generated.

Furthermore, the light source apparatus 3003 may be configured to be capable of supplying light in a predetermined wavelength band that accommodates special light observation. In special light observation, for example, wavelength dependence of absorption of light by body tissue is utilized. Specifically, predetermined tissue such as a blood vessel of a superficial portion of a mucous membrane is photographed with high contrast by irradiating light with a narrower band than irradiation light during normal observation (in other words, white light). Alternatively, in special light observation, fluorescent observation may be performed in which an image is obtained using fluorescent light generated by irradiating excitation light. In fluorescent observation, body tissue may be irradiated with excitation light and fluorescent light from the body tissue can be observed, a reagent such as indocyanine green (ICG) can be locally injected into body tissue and the body tissue can be irradiated with excitation light corresponding to a fluorescent wavelength of the reagent to obtain a fluorescent image, and the like. The light source apparatus 3003 may be configured to be capable of supplying narrow-band light and/or excitation light that accommodates such special light observation.

### Twelfth Embodiment

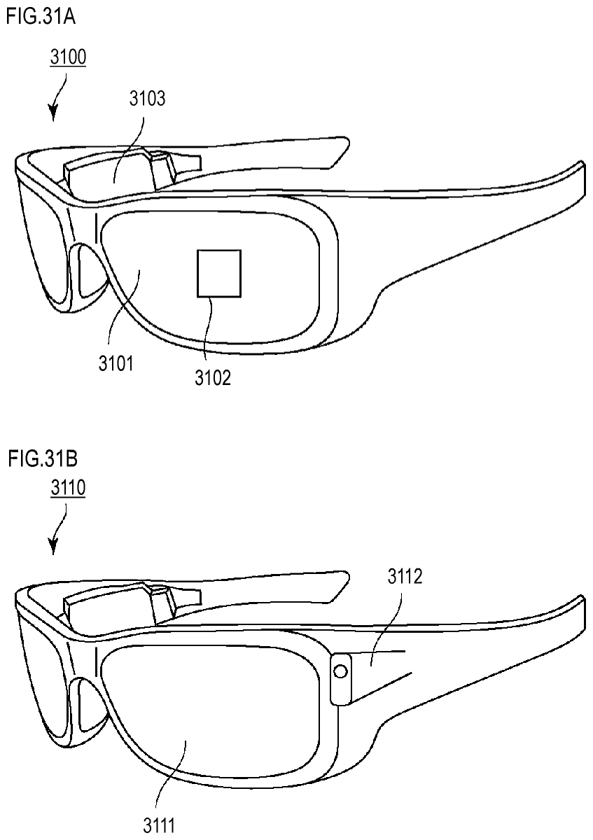

A photoelectric conversion system according to the present embodiment will be described with reference to FIGS. 31A and 31B. FIG. 31A illustrates eyeglasses 3100 (smart glasses) that is the photoelectric conversion system according to the present embodiment. The eyeglasses 3100 have a photoelectric conversion apparatus 3102. The photoelectric conversion apparatus 3102 is the photoelectric conversion apparatus (imaging apparatus) according to any one of the embodiments described above. In addition, a display apparatus including a light-emitting apparatus such as an OLED or an LED may be provided on a rear surface side of a lens 3101. There may be one or a plurality of photoelectric conversion apparatuses 3102. Alternatively, a plurality of types of photoelectric conversion apparatuses may be used in combination. An arrangement position of the photoelectric conversion apparatus 3102 is not limited to that shown in FIG. 31A.

The eyeglasses 3100 further include a control apparatus 3103. The control apparatus 3103 functions as a power source that supplies power to the photoelectric conversion apparatus 3102 and the display apparatus described above. In addition, the control apparatus 3103 controls operations of the photoelectric conversion apparatus 3102 and the display apparatus. An optical system for collecting light to the photoelectric conversion apparatus 3102 is formed in the lens 3101.

FIG. 31B illustrates eyeglasses 3110 (smart glasses) according to one application example. The eyeglasses 3110 include a control apparatus 3112 and the control apparatus 3112 is mounted with a photoelectric conversion apparatus that corresponds to the photoelectric conversion apparatus 3102 and a display apparatus. An optical system for projecting light emitted from the photoelectric conversion apparatus inside the control apparatus 3112 and the display apparatus is formed in the lens 3111 and an image is projected onto the lens 3111. The control apparatus 3112 functions as a power source that supplies power to the photoelectric conversion apparatus and the display apparatus and, at the same time, controls operations of the photoelectric conversion apparatus and the display apparatus. The control apparatus may have a line-of-sight detecting unit that detects a line-of-sight of a wearer. Infrared light may be used to detect a line-of-sight. An infrared light-emitting unit emits infrared light to the eyes of a user who is looking at a display image. A picked-up image of the eyes can be obtained by having an imaging unit including a light-receiving element detect reflected light from the eyes of emitted infrared light. Providing reducing means that reduces light from the infrared light-emitting unit to the display unit in a plan view enables a decline in image quality to be mitigated.

A line-of-sight of the user with respect to a display image can be detected from a picked-up image of eyes obtained by imaging with infrared light. Any known method can be applied to line-of-sight detection using a picked-up image of the eyes. For example, a line-of-sight detection method based on a Purkinje image due to reflection of irradiation light by the cornea can be used.

More specifically, line-of-sight detection processing based on a pupil-corneal reflection method is performed. Using the pupil-corneal reflection method, a line-of-sight of a user is detected by calculating a line-of-sight vector that represents an orientation (a rotation angle) of the eyes based on an image of a pupil included in a picked-up image of the eyes and a Purkinje image. The display apparatus according to the present embodiment may have a photoelectric conversion apparatus including a light-receiving element and a display image of the display apparatus may be controlled based on line-of-sight information of the user from the photoelectric conversion apparatus.

Specifically, the display apparatus determines, based on the line-of-sight information, a first field-of-view region which the user focuses on and a second field-of-view region other than the first field-of-view region. The first field-of-view region and the second field-of-view region may be determined by the control apparatus of the display apparatus or regions determined by an outside control apparatus may be received as the first field-of-view region and the second field-of-view region. In a display region of the display apparatus, a display resolution of the first field-of-view region may be controlled to be higher than a display resolution of the second field-of-view region. In other words, the resolution of the second field-of-view region may be set lower than that of the first field-of-view region.

In addition, the display region may have a first display region and a second display region that differs from the first display region, and a region with high priority may be determined from the first display region and the second display region based on line-of-sight information. The first display region and the second display region may be determined by the control apparatus of the display apparatus or regions determined by an outside control apparatus may be received as the first display region and the second display region. A resolution of a region with high priority may be controlled to be higher than a resolution of a region other than the region with high priority. In other words, a resolution of a region of which a priority is relatively low can be lowered.

It should be noted that an AI (Artificial Intelligence) may be used to determine the first field-of-view region and a region with high priority. The AI may be a model configured to use an image of the eyes and a direction actually viewed by the eyes in the image as teacher data to estimate, from the image of the eyes, an angle of a line-of-sight and a distance to an object ahead of the line-of-sight. An AI program may be included in the display apparatus, the photoelectric conversion apparatus, or an external apparatus. When the external apparatus includes an AI program, an inference result by an AI is sent to the display apparatus via communication.

Display control based on visual recognition and detection can be preferably applied to smart glasses further including a photoelectric conversion apparatus that captures images of the outside. The smart glasses are capable of displaying captured external information in real-time.

### Thirteenth Embodiment

The photoelectric conversion apparatuses and the photoelectric conversion systems described above can be applied to, for example, electronic devices such as so-called smartphones and tablets.

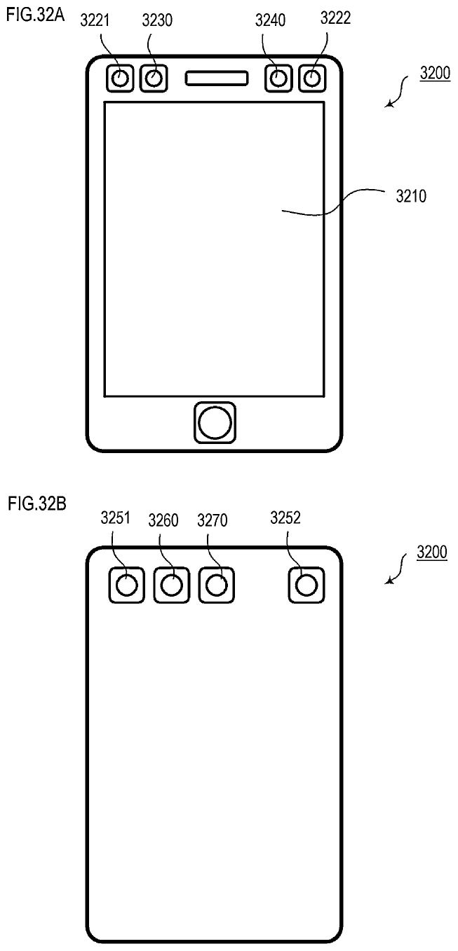

FIGS. 32A and 32B are diagrams showing an example of an electronic device 3200 to which a photoelectric conversion apparatus is mounted. FIG. 32A shows a front surface side of the electronic device 3200 and FIG. 32B shows a rear surface side of the electronic device 3200.

As shown in FIG. 32A, a display 3210 that displays an image is arranged at a center of the front surface of the electronic device 3200. In addition, front cameras 3221 and 3222 that use the photoelectric conversion apparatus, an IR light source 3230 that emits infrared light, and a visible light source 3240 that emits visible light are arranged along an upper side of the front surface of the electronic device 3200.

Furthermore, as shown in FIG. 32B, rear cameras 3251 and 3252 that use the photoelectric conversion apparatus, an IR light source 3260 that emits infrared light, and a visible light source 3270 that emits visible light are arranged along an upper side of the rear surface of the electronic device 3200.

In the electronic device 3200 configured as described above, by applying the photoelectric conversion apparatus described above, for example, an image with higher quality can be captured and a distance to a subject can be measured with high accuracy. Note that the photoelectric conversion apparatus can be applied to other electronic devices such as an infrared sensor, a ranging sensor using an active infrared light source, a security camera, and a personal authentication camera or a biometric camera. As a result, accuracy and performance of such electronic devices can be improved.

### Fourteenth Embodiment

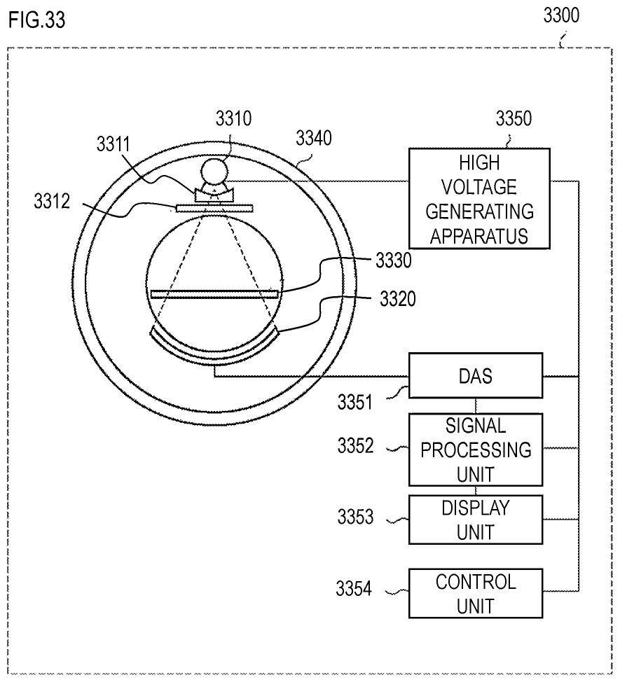

FIG. 33 is a block diagram of an X-ray CT apparatus according to the present embodiment. The photoelectric conversion apparatuses and the photoelectric conversion systems described above can be applied to a detector of the X-ray CT apparatus. An X-ray CT apparatus 3300 according to the present embodiment includes an X-ray generating unit 3310, a wedge 3311, a collimator 3312, an X-ray detecting unit 3320, and a top plate 3330. Furthermore, the X-ray CT apparatus 3300 includes a rotating frame 3340, a high voltage generating apparatus 3350, a data collection apparatus (DAS: Data Acquisition System) 3351, a signal processing unit 3352, a display unit 3353, and a control unit 3354.

The X-ray generating unit 3310 is constituted of, for example, a vacuum tube that generates X-rays. A high voltage from the high voltage generating apparatus 3350 and a filament current are supplied to the vacuum tube of the X-ray generating unit 3310. An X-ray is generated as thermions are radiated from a cathode (filament) toward an anode (target).

The wedge 3311 is a filter that adjusts an X-ray dosage radiated from the X-ray generating unit 3310. The wedge 3311 attenuates the X-ray dosage so that X-rays radiated from the X-ray generating unit 3310 toward the object are distributed as determined in advance. The collimator 3312 is constituted of a lead plate or the like that narrows down an irradiation range of the X-rays having passed through the wedge 3311. An X-ray generated by the X-ray generating unit 3310 is molded into a cone beam shape via the collimator 3312 and radiated to the object on the top plate 3330.

The X-ray detecting unit 3320 is constructed by using the photoelectric conversion apparatus or the photoelectric conversion system described above. The X-ray detecting unit 3320 detects an X-ray having passed through the object from the X-ray generating unit 3310 and outputs a signal corresponding to the X-ray dosage to the DAS 3351.

The rotating frame 3340 has an annular shape and is configured to be rotatable. The X-ray generating unit 3310 (the wedge 3311 and the collimator 3312) and the X-ray detecting unit 3320 are arranged so as to oppose each other inside the rotating frame 3340. The X-ray generating unit 3310 and the X-ray detecting unit 3320 are rotatable together with the rotating frame 3340.

The high voltage generating apparatus 3350 includes a boost circuit and outputs a high voltage to the X-ray generating unit 3310. The DAS 3351 includes an amplifier circuit and an A/D converter circuit and outputs a signal from the X-ray detecting unit 3320 as digital data to the signal processing unit 3352.

The signal processing unit 3352 includes a CPU (Central Processing Unit), a ROM (Read Only Memory), and a RAM (Random Access Memory) and is capable of executing image processing of digital data and the like. The display unit 3353 includes a flat display apparatus or the like and is capable of displaying an X-ray image. The control unit 3354 includes a CPU, a ROM, and a RAM and controls operations of the entire X-ray CT apparatus 3300.

### Fifteenth Embodiment

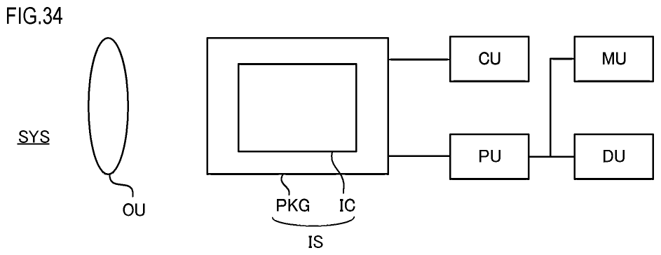

A photoelectric conversion system according to an eleventh embodiment will be described with reference to FIG. 34. FIG. 34 is a block diagram showing a schematic configuration of an imaging system SYS that is the photoelectric conversion system according to the eleventh embodiment. The imaging system SYS includes at least the photoelectric conversion apparatus according to any one of the embodiments described above and a signal processing unit that processes signals output from the photoelectric conversion apparatus.

The imaging system SYS is an information terminal that includes a camera and a photography function. The imaging system SYS is constructed using an imaging apparatus IS. The imaging apparatus IS can further include a package PKG that houses an imaging device IC. The package PKG can include a substrate on which the imaging device IC is fixed and a lid body that opposes the imaging device IC. The package PKG can include a connecting member (a member that connects a terminal provided on the substrate and a terminal provided on the imaging device IC) to each other. The imaging apparatus IS can mount a plurality of the imaging devices IC to a common package PKG by arranging the imaging devices IC side by side. Alternatively, the imaging apparatus IS can mount the imaging device IC and another semiconductor device IC to a common package PKG by stacking the imaging device IC and the semiconductor device IC on top of each other.

The imaging system SYS can include an optical system OU (optical apparatus) that forms an image on the imaging apparatus IS. In addition, the imaging system SYS can include at least any of a control apparatus CU, a processing apparatus PU, a display apparatus DU, and a storage apparatus MU. The control apparatus CU controls the imaging apparatus IS and the processing apparatus PU processes a signal obtained from the imaging apparatus IS. Furthermore, the display apparatus DU displays an image obtained from the imaging apparatus IS and the storage apparatus MU stores the image obtained from the imaging apparatus IS.

### OTHER EMBODIMENTS

While various apparatuses have been explained in the embodiments described above, a mechanical apparatus may be further provided. A mechanical apparatus in a camera can drive parts of the optical system for the purposes of zooming, focusing, and shutter operations. Alternatively, the mechanical apparatus in the camera can move the photoelectric conversion apparatus for vibration insulation.

In addition, the apparatus may be transportation equipment such as a vehicle, a ship, or a flight vehicle. A mechanical apparatus in the transportation equipment may be used as a moving apparatus. The apparatus as transportation equipment is suitable as an apparatus that transports the photoelectric conversion apparatus or an apparatus that assists and/or automates driving (operation) using the photography function. A processing apparatus for assisting and/or automating driving (operation) can perform processing for operating the mechanical apparatus as a moving apparatus based on information obtained by the photoelectric conversion apparatus.

The embodiments described above can be appropriately modified without departing from the technical concepts of the invention. It is to be understood that disclosed contents of the present specification include not only matters described in the present specification but also all matters that may be comprehended from the present specification and from the drawings that accompany the present specification. In addition, disclosed contents of the present specification include complementary sets of concepts described in the present specification. In other words, supposing that the present specification includes a description reading, for example, “A is larger than B”, it is assumed that the present specification also discloses that “A is not larger than B” even though a description of “A is not larger than B” has been omitted. This is because, the presence of a description to the effect that “A is larger than B” is premised on the fact that a case where “A is not larger than B” is being taken into consideration.

In the present specification, there may be cases where expressions such as “A or B”, “at least one of A and B”, “at least one of A and/or B”, “one or more of A and/or B”, and the like are used. In such a case, all possible combinations of the listed items can be included unless explicitly defined otherwise. In other words, the expressions presented above are understood to disclose all of a case where at least one A is included, a case where at least one B is included, and a case where both at least one A and at least one B are included. This logic is similarly applied to combinations of three or more elements.

According to the present invention, in a configuration in which a separation portion includes a conductor, a suppression effect of crosstalk can be enhanced while suppressing noise attributable to an electric field between the separation portion and an APD.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2023-165204, filed on Sep. 27, 2023 and Japanese Patent Application No. 2024-098500, filed on Jun. 19, 2024, which are hereby incorporated by reference herein in their entirety.

What is claimed is:

1. A photoelectric conversion apparatus, comprising:
a substrate including a first surface and a second surface, the second surface opposing the first surface and being a light incidence surface;
a plurality of photoelectric conversion elements which are provided on the substrate, and each of which includes an avalanche photodiode; and
a separation portion which separates the plurality of photoelectric conversion elements, wherein
each of the plurality of photoelectric conversion elements includes a first semiconductor region of a first conductivity type to which a first potential is applied and which constitutes the avalanche photodiode and a second semiconductor region of a second conductivity type which constitutes the avalanche photodiode,
the separation portion includes a conductor to which a second potential that differs from the first potential is applied and an insulator which is provided between the photoelectric conversion element and the conductor,
in a direction parallel to the first surface, a thickness of the insulator at a first depth that is a same depth as the first semiconductor region is greater than the thickness of the insulator at a third depth positioned between a second depth that is a same depth as the second semiconductor region and the second surface,
the photoelectric conversion apparatus further comprises a third semiconductor region of the second conductivity type which encloses the insulator, and
in the direction parallel to the first surface, a thickness of the insulator at the first depth is greater than a sum of a thickness of the third semiconductor region and a thickness of the insulator at the third depth.

2. A photoelectric conversion apparatus, comprising:
a substrate including a first surface and a second surface, the second surface opposing the first surface and being a light incidence surface;
a first photoelectric conversion element and a second photoelectric conversion element which are provided on the substrate, each of which including an avalanche photodiode;
a separation portion which is positioned between the first photoelectric conversion element and the second photoelectric conversion element and which at least separates a first surface side; and
a first wiring layer which is arranged on the first surface side of the substrate, wherein
the separation portion includes a conductor, a first insulator, and a second insulator,
the first insulator and the second insulator are arranged between the conductor and the first photoelectric conversion element,
a refractive index of the second insulator is higher than a refractive index of the first insulator, and
the second insulator extends to the first wiring layer.

3. The photoelectric conversion apparatus according to claim 1, wherein
in the direction parallel to the first surface, a thickness of the insulator at the first depth is greater than a thickness of the insulator at the second depth.

4. The photoelectric conversion apparatus according to claim 1, wherein
the insulator is provided so as to enclose the conductor.

5. The photoelectric conversion apparatus according to claim 1, wherein
the conductor is present at the first depth but not present at the third depth.

6. The photoelectric conversion apparatus according to claim 1, further comprising:
an anode electrode provided on the second surface side.

7. The photoelectric conversion apparatus according to claim 1, wherein
the conductor functions as an anode electrode.

8. A photoelectric conversion system, comprising:
the photoelectric conversion apparatus according to claim 1; and
a signal processing portion which generates an image by using a signal output by the photoelectric conversion apparatus.

9. A photoelectric conversion system, comprising:
the photoelectric conversion apparatus according to claim 2; and
a signal processing portion which generates an image by using a signal output by the photoelectric conversion apparatus.

10. A moving body comprising the photoelectric conversion apparatus according to claim 1, further comprising:
a control portion which controls movement of the moving body by using a signal output by the photoelectric conversion apparatus.

11. A moving body comprising the photoelectric conversion apparatus according to claim 2, further comprising:
a control portion which controls movement of the moving body by using a signal output by the photoelectric conversion apparatus.

12. Equipment comprising the photoelectric conversion apparatus according to claim 1, the equipment further comprising at least any of:
an optical apparatus corresponding to the photoelectric conversion apparatus;
a control apparatus that controls the photoelectric conversion apparatus;
a processing apparatus that processes a signal output from the photoelectric conversion apparatus;
a display apparatus that displays information obtained by the photoelectric conversion apparatus;
a storage apparatus that stores information obtained by the photoelectric conversion apparatus; and
a mechanical apparatus that operates on a basis of information obtained by the photoelectric conversion apparatus.

13. Equipment comprising the photoelectric conversion apparatus according to claim 2, the equipment further comprising at least any of:
an optical apparatus corresponding to the photoelectric conversion apparatus;
a control apparatus that controls the photoelectric conversion apparatus;
a processing apparatus that processes a signal output from the photoelectric conversion apparatus;
a display apparatus that displays information obtained by the photoelectric conversion apparatus;
a storage apparatus that stores information obtained by the photoelectric conversion apparatus; and
a mechanical apparatus that operates on a basis of information obtained by the photoelectric conversion apparatus.
